(19) United States
(12) Patent Application Publication
(10) Pub. No.: US 2012/0250264 A1
(43) Pub. Date: Oct. 4, 2012

(54) MEMORY MODULE HAVING MEMORY CHIP AND REGISTER BUFFER

(75) Inventors: Fumiyuki OSANAI, Tokyo (JP); Toshio SUGANO, Tokyo (JP); Masayuki NAKAMURA, Tokyo (JP)

(73) Assignee: ELPIDA MEMORY, INC., Tokyo (JP)

(21) Appl. No.: 13/431,498

(22) Filed: Mar. 27, 2012

(30) Foreign Application Priority Data
Mar. 28, 2011 (JP) 2011-070011

(51) Int. Cl. H05K 7/00

(52) U.S. Cl. 361/728

(57) ABSTRACT

Disclosed herein is a memory module that includes a register buffer and a memory chip each mounted on a module substrate. Each of the command address output terminals belonging to the first group provided on the register buffer is connected to an associated one of the command address input terminals belonging to the first group provided on the memory chip through associated ones of the plurality of contact plugs and the first wiring layer. Each of the command address output terminals belonging to the second group provided on the register buffer is connected to an associated one of the command address input terminals belonging to the second group provided on the memory chip through associated ones of the plurality of contact plugs and the second wiring layer.

### BACKGROUND OF THE INVENTION

1. Field of the Invention

The present invention relates to a memory module, and more particularly to a memory module that includes a register buffer for supplying command address signals to memory chips.

2. Description of Related Art

Memory modules such as a dual inline memory module (DIMM) are configured so that a large number of memory chips such as dynamic random access memories (DRAMs) are mounted on a module substrate (see Japanese Patent Application Laid-open No. 2005-141747). Such a memory module is plugged into a memory slot arranged on a motherboard, whereby data is transferred from/to a memory controller.

There has recently been a need for higher capacity memory modules. To increase the memory capacity of a memory module, it is effective to increase the number of memory chips mounted on a module substrate.

In some memory modules, command address signals are supplied to memory chips through a register buffer. If the number of memory chips is increased, the density of wiring on the module substrate that connects the register buffer and the memory chips increases accordingly. There has thus been a problem that the signal quality of the command address signals can drop depending on the wiring layout. In view of the foregoing, the inventors have made an intensive study to determine what kind of wiring layout enables supply of high quality command address signals from a register buffer to a large number of memory chips.

### SUMMARY

In one embodiment, there is provided a memory module that includes: a module substrate that includes a plurality of wiring layers including at least first and second wiring layers, and a plurality of contact plugs penetrating through the plurality of wiring layers; a register buffer that is mounted on the module substrate and includes a plurality of output terminals classified into at least first and second groups; and a memory chip that is mounted on the module substrate and includes a plurality of input terminals classified into at least first and second groups. Each of the output terminals belonging to the first group is connected to an associated one of the input terminals belonging to the first group through associated ones of the plurality of contact plugs and the first wiring layer. Each of the output terminals belonging to the second group is connected to an associated one of the input terminals belonging to the second group through associated ones of the plurality of contact plugs and the second wiring layer.

In another embodiment, there is provided a module that includes: a module substrate includes a plurality of wiring layers including at least first and second wiring layers, and first and second contact plugs, each of the first and second contact plugs penetrating through the wiring layers; a resister buffer mounted on the module substrate and including first and second output terminals; and a plurality of chips mounted on the module substrate, each of the chips including first and second input terminals. The first output terminal of the resister buffer is commonly connected to the first input terminals of the chips through the first contact plug and the first wiring layer. The second output terminal of the resister buffer is commonly connected to the second input terminals of the chips through the second contact plug and the second wiring layer.

### BRIEF DESCRIPTION OF THE DRAWINGS

FIG. 1is a schematic diagram indicative of an embodiment of the configuration of a memory module 100 according to a preferred embodiment of the present invention;

FIG. 2A is a diagram describing memory chips 201 to 236 which are mounted on a surface side of a module substrate 110;

FIG. 2B is a diagram describing memory chips 237 to 272 which are mounted on the back side of the module substrate 110 and shows the memory chips 237 to 272 mounted on the back side of the module substrate 110 as transparently seen from the surface side of the module substrate 110;

FIG. 3 is a schematic sectional view indicative of an embodiment of the memory module 100 according to the present embodiment;

FIG. 4 is a schematic diagram indicative of an embodiment of a memory system that uses the memory module 100 according to the present embodiment;

FIG. 5 is a functional block diagram indicative of an embodiment of a register buffer 300;

FIG. 6 is a schematic diagram for explaining the flow of command address signals CA on the module substrate 110;

FIG. 7 is a schematic diagram for explaining the flow of some of control signals CTL on the module substrate 110;

FIG. 8 is a schematic diagram for explaining the flow of clock signals CK on the module substrate 110;

FIG. 9 is a schematic diagram for explaining the flow of data DQ on the module substrate 110 and combinations of memory chips 200 to be connected to the same wiring with respect to data DQ and data strobe signals DQS;

FIG. 10 is a schematic cross-sectional view showing wiring layers included in the module substrate 110;

FIG. 11 is a schematic diagram for explaining in detail portions of wirings L1 to L8 corresponding to half the command address signals CA in an area 100A shown in FIG. 1;

FIG. 12A schematically shows the layout of the command address output terminals on the register buffer 300;

FIG. 12B schematically shows the layout of command address input terminals on memory chips 200 that belong to Ranks 0 and 1;

FIG. 12C schematically shows the layout of command address input terminals on memory chips 200 that belong to Ranks 2 and 3;

FIG. 13 is a schematic diagram for explaining the wire connection method of the wirings L1 to L4 according to a reference example;

FIG. 14 is a sectional view for explaining the connection relationship between the wirings in an area 100B shown in FIG. 11;

FIG. 15 is a schematic diagram for detailing portions of the wirings L1 to L8 corresponding to the remaining half of the command address signals CA in the area 100A shown in FIG. 1;

FIG. 16 is a sectional view for explaining the connection relationship between the wirings in an area 100C shown in FIG. 15;

FIG. 17 is a diagram indicative of an embodiment of the layout of the group of terminals G1 formed on the register buffer 300 in more detail;

FIG. 18 is a general plan view for explaining the connection relationship between the wirings L3 and L4 formed in the wiring layers Layer7 and Layer10 and command address output terminals 322;

FIG. 19 is a diagram indicative of an embodiment of detailed layout of command address input terminals 291 formed on memory chips 200;

FIG. 20 is a diagram indicative of an embodiment of the positional relationship of the memory chips 200 shown in FIG. 19;

FIG. 21 is a table indicative of an embodiment of the correspondence between the mirrored terminals;

FIG. 22 is a general plan view for explaining the connection relationship between the wirings L3 and L4 formed in the wiring layers Layer7 and Layer10 and command address input terminals 291;

FIG. 23 is a diagram showing detailed layout of data input/output terminals 292 formed on memory chips 200.

FIG. 24 is a diagram indicative of an embodiment of the positional relationship of the memory chips 200 shown in FIG. 23;

FIG. 25 is a table indicative of an embodiment of the correspondence between the mirrored terminals DQ0 to DQ3;

FIG. 26 is a schematic diagram for explaining the flow of command address signals CA according to a first modification;

FIG. 27 is a schematic diagram for explaining the flow of command address signals CA according to a second modification;

FIG. 28 is a schematic diagram for explaining the flow of command address signals CA according to a third modification;

FIG. 29 is a schematic diagram for explaining the flow of command address signals CA according to a fourth modification;

FIG. 30 is a schematically diagram indicative of an embodiment of signal lines from a command address output terminal 322 included in the group of terminals G1 of the register buffer 300 to memory chips 200, the model shown in FIG. 30 is based on the connection relationship shown in FIG. 6;

FIG. 31 is a diagram indicative of an embodiment of a group of memory chips 200C that is extracted from FIG. 30;

FIG. 32 is a table indicative of an embodiment of design examples of the signal lines TL1 to TL5; and

FIGS. 33A and 33B are charts indicative of an embodiment of results of simulation of the signal quality of command address signals CA with signal lines TL1 to TL5 of different lengths, where FIG. 33A shows an example where all the signal lines TL1 to TL5 have the minimum possible design length, and FIG. 33B shows an example where the signal lines TL1 to TL5 are designed according to design example 1 shown in FIG. 32.

### DETAILED DESCRIPTION OF THE EMBODIMENTS

Preferred embodiments of the present invention will be explained below in detail with reference to the accompanying drawings.

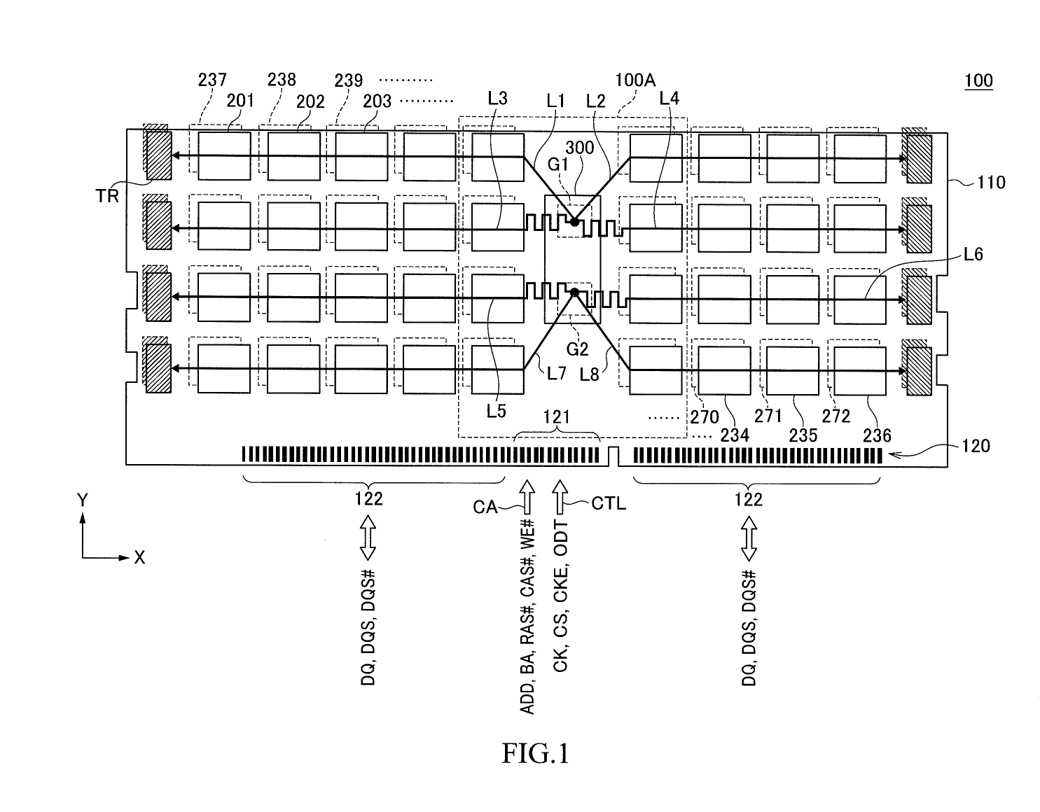

Referring now to FIG. 1, the memory module 100 according to the present embodiment includes a module substrate 110 which includes a plurality of wiring layers, and 72 memory chips 201 to 272 and a register buffer 300 which are mounted on the module substrate 110. As employed herein, the memory chips 201 to 272 may be referred to simply as “memory chips 200” when no distinction is needed.

The module substrate 110 is a printed-circuit board having multilayer wiring. The module substrate 110 has a generally rectangular planar shape with long sides in the X direction shown in FIG. 1 and short sides in the Y direction.

A plurality of connectors 120 are formed on one side of the module substrate 110 along the X direction, the long side. The connectors 120 are terminals for electrical connection with a memory controller through a memory slot to be described later. The connectors 120 are classified into connectors 121 and connectors 122. The connectors 121 are ones to which command address signals CA and control signals CTL are supplied from the memory controller. The connectors 122 are intended to output read data to the memory controller or input write data from the memory controller. In the present embodiment, the number of pins of the connectors 122 for data is, though not limited to, 72. Consequently, 72 bits of read data or write data can be simultaneously input/output.

As employed in the present embodiment, “command address signals” refer to a group of signals including an address signal ADD, a bank address signal BA, a row address strobe signal RAS#, a column address strobe signal CAS#, and a write enable signal WE#. Although not limited in particular, the address signal ADD is a 16-bit signal, the bank address signal BA 3-bit, and the row address strobe signal RAS#, column address strobe signal CAS#, and write enable signal WE# are 1-bit each. The command address signals CA are thus signals of 22 bits in total. In the present specification and drawings, the address signal ADD and the bank address signal BA may be referred to simply as an address signal ADD when no distinction is needed. In the present specification and drawings, the row address strobe signal RAS#, the column address strobe signal CAS#, and the write enable signal WE# may be referred to collectively as command signals CMD.

In the present embodiment, “control signals” refer to a group of signals including clock signals CK0 to CK3 and CK0# to CK3#, chip select signals CS0# to CS3#, clock enable signals CKE0 to CKE3, and on-die termination signals ODT0 and ODT1. The clock signals CK0 to CK3 and the clock signals CK0# to CK3# are signals complementary to each other. The clock signals CK0 to CK3 and CK0# to CK3# are supplied to memory chips 200 that are mounted on respective corresponding areas. The chip select signals CS0# to CS3# and the clock enable signals CKE0 to CKE3 are signals for activating respective corresponding Ranks (to be described later). The on-die termination signals ODT0 and ODT1 are signals for making respective corresponding Ranks function as a termination resistor. In the present specification and drawings, when no distinction is needed, the clock signals CK0 to CK3 and CK0# to CK3# may be referred to collectively as clock signals CK. The chip select signals CS0# to CS3# may be referred to collectively as chip select signals CS. The clock enable signals CKE0 to CKE3 may be referred to collectively as clock enable signals CKE. The on-die termination signals ODT0 and ODT1 may be referred to collectively as on-die termination signals ODT.

The memory chips 201 to 272 are DRAMs, for example. Of these, 36 memory chips 201 to 236 are mounted on one of the surfaces of the module substrate 110. The remaining 36 memory chips 237 to 272 are mounted on the other surface of the module substrate 110. The memory chips 201 to 236 and the memory chips 237 to 272 are mounted in respective opposite positions across the module substrate 110. For example, the memory chip 201 and the memory chip 237 are mounted on the surface and back of the module substrate 110 in the same planar positions, i.e., at the same X and Y coordinates. For better viewability, FIG. 1 shows each pair of memory chips 200 arranged on the surface and back of the module substrate 110 in staggered planar positions. In fact, as mentioned above, such memory chips 200 have the same planar positions.

The memory module 100 according to the present embodiment has a so-called four-Rank configuration. A Rank refers to a memory space to be exclusively selected. The same addresses are allocated for the Ranks. The chip select signals (CS0# to CS3#) are exclusively activated and the clock enable signals (CKE0 to CKE3) are exclusively activated to select any one of the Ranks.

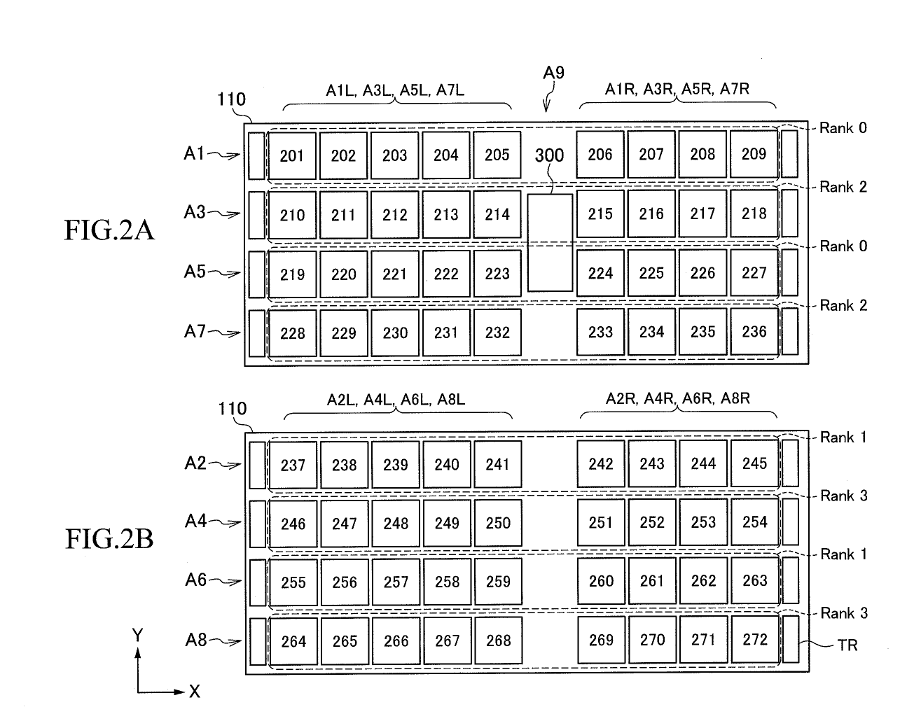

Turning to FIG. 2A, the memory chips 201 to 209 and 219 to 227 mounted on the surface side of the module substrate 110 constitute a Rank 0. The memory chips 201 to 209 are mounted on a memory chip mounting area A1 which is defined on the surface side of the module substrate 110. The memory chips 219 to 227 are mounted on a memory chip mounting area A5 which is defined on the surface side of the module substrate 110. The memory chips 237 to 245 and 255 to 263 mounted on the back side of the Rank 0 constitute a Rank 1. The memory chips 237 to 245 are mounted on a memory chip mounting area A2 which is defined on the back side of the module substrate 110. The memory chips 255 to 263 are mounted on a memory chip mounting area A6 which is defined on the back side of the module substrate 110.

The memory chips 210 to 218 and 228 to 236 mounted on the surface side of the module substrate 110 constitute a Rank 2. The memory chips 210 to 218 are mounted on a memory chip mounting area A3 which is defined on the surface side of the module substrate 110. The memory chips 228 to 236 are mounted on a memory chip mounting area A7 which is defined on the surface side of the module substrate 110. The memory chips 246 to 254 and 264 to 272 mounted on the back side of the Rank 2 constitute a Rank 3. The memory chips 246 to 254 are mounted on a memory chip mounting area A4 which is defined on the back side of the module substrate 110. The memory chips 264 to 272 are mounted on a memory chip mounting area A8 which is defined on the back side of the module substrate 110.

All the memory chip mounting areas A1 to A8 extend in the X direction. The memory chip mounting areas A1 to A8 each include nine memory chips 200 which are arranged in the X direction. The memory chip mounting areas A1 and A2, A3 and A4, A5 and A6, and A7 and A8 are located in the same planar positions on the surface and back of the module substrate 110, respectively.

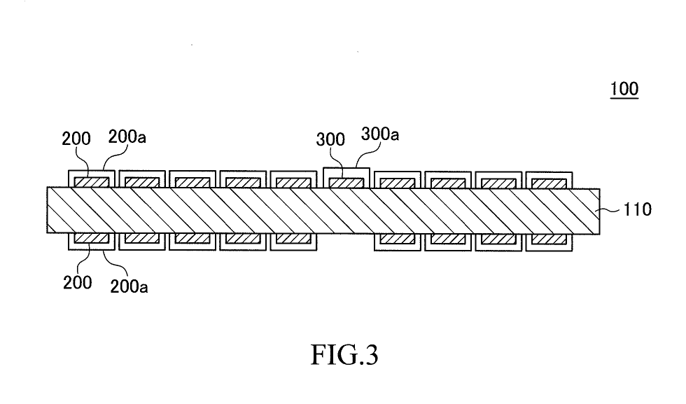

Turning to FIG. 3, according to the present embodiment, a single memory chip 200 is enclosed in a package 200a. The 72 memory chips 200 mounted on the module substrate 110 are enclosed in respective different packages 200a. That is, there are 72 packages 200a mounted on the module substrate 110. The register buffer 300 is enclosed in a package 300a. In the present embodiment, the memory chips 200 are mounted on the module substrate 110 with a not so high mounting density since the packages 200a each include only one memory chip 200.

Turning to FIG. 2A, the register buffer 300 is mounted on a register buffer mounting area A9 which divides the memory chip mounting areas A1, A3, A5, and A7 in the X direction. The register buffer mounting area A9 is located on the surface side of the module substrate 110. No register buffer mounting area is provided on the back side. As mentioned previously, each pair of memory chips 200 lying on the surface and back of the module substrate 110 have the same planar positions. No chip is thus mounted on the back side of the register buffer mounting area A9. Consequently, the memory chip mounting areas A1 to A8 are divided into first portions AIL to A8L that lie on one side (left in FIGS. 2A and 2B) and second portions A1R to A8R that lie on the other side (right in FIGS. 2A and 2B) with respect to the register buffer 300.

Command address signals CA output from the register buffer 300 are supplied to the memory chips 201 to 272 through wirings L1 to L8 shown in FIG. 1. The command address signals CA are common to all the memory chips 201 to 272. As shown in FIG. 1, the command address signals CA are supplied to the memory chips 201 to 272 through the eight separate systems of the wirings L1 to L8.

Specifically, the command address signals CA are supplied to the memory chips 201 to 205 and 237 to 241 mounted on the left portions A1L and A2L of the memory chip mounting areas A1 and A2 through the wiring L1. The command address signals CA are supplied to the memory chips 206 to 209 and 242 to 245 mounted on the right portions A1R and A2R of the memory chip mounting areas A1 and A2 through the wiring L2. The command address signals CA are supplied to the memory chips 210 to 214 and 246 to 250 mounted on the left portions A3L and A4L of the memory chip mounting areas A3 and A4 through the wiring L3. The command address signals CA are supplied to the memory chips 215 to 218 and 251 to 254 mounted on the right portions A3R and A4R of the memory chip mounting areas A3 and A4 through the wiring L4. The command address signals CA are supplied to the memory chips 219 to 223 and 255 to 259 mounted on the left portions A5L and A6L of the memory chip mounting areas A5 and A6 through the wiring L5. The command address signals CA are supplied to the memory chips 224 to 227 and 260 to 263 mounted on the right portions A5R and A6R of the memory chip mounting areas A5 and A6 through the wiring L6. The command address signals CA are supplied to the memory chips 228 to 232 and 264 to 268 mounted on the left portions A7L and A8L of the memory chip mounting areas A7 and A8 through the wiring L7. The command address signals CA are supplied to the memory chips 233 to 236 and 269 to 272 mounted on the right portions A7R and A8R of the memory chip mounting areas A7 and A8 through the wiring L8.

The register buffer 300 includes command address output terminals for outputting the command address signals CA. As shown in FIG. 1, the register buffer 300 according to the present embodiment has two groups of terminals G1 and G2, both of which include command address output terminals. The command address signals CA output from the command address output terminals included in the group of terminals G1 and the command address signals CA output from the command address output terminals included in the group of terminals G2 are the same. The command address signals CA output from the command address output terminals included in the group of terminals G1 are supplied to the memory chips 201 to 218 and 237 to 254 through the wirings L1 to L4. The command address signals CA output from the command address output terminals included in the group of terminals G2 are supplied to the memory chips 219 to 236 and 255 to 272 through the wirings L5 to L8.

As shown in FIG. 1, the group of terminals G1 and the group of terminals G2 are juxtaposed in the Y direction. The group of terminals G1 is closer to the memory chips 201 to 218 and 237 to 254 which are mounted on the memory chip mounting areas A1 to A4. The group of terminals G2 is closer to the memory chips 219 to 236 and 255 to 272 which are mounted on the memory chip mounting areas A5 to A8. Since the command address output terminals of the register buffer 300 are allocated in both the groups of terminals G1 and G2, it is possible to reduce the wiring length of the wirings L1 to L8. This also facilitates resolving differences in wiring length between the wirings L1 to L8. In the present embodiment, the wirings L3 to L6 are laid to make a detour in a meandering configuration near the register buffer 300, thereby resolving a difference in wiring length from the wirings L1, L2, L7, and L8. The provision of the two groups of terminals G1 and G2 also increases the degree of freedom of the wiring layout near the register buffer 300, and allows a reduction in wiring density.

Termination resistors TR are connected to the ends of the respective wirings L1 to L8. The termination resistors TR function to prevent reflection of signals including the command address signals CA output from the register buffer 300. As shown in FIG. 1, the termination resistors TR are arranged on both ends of the module substrate 110 in the X direction.

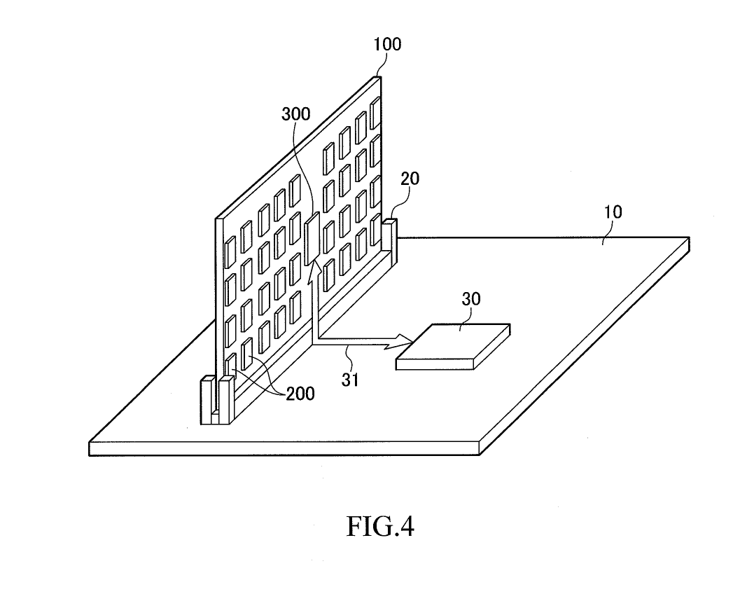

Turning to FIG. 4, the memory system includes a motherboard 10. The motherboard 10 has a memory slot 20. The memory module 100 is inserted into the memory slot 20. A memory controller 30 is mounted on the motherboard 10. The memory controller 30 is connected to the memory module 100 through a wiring 31 formed on the motherboard 10 and through the memory slot 20. The memory controller 30 is a semiconductor chip for controlling the memory module 100.

In the present embodiment, the memory controller 30 and the memory chips 200 on the memory module 100 transmit and receive all signals through the register buffer 300. This makes the load capacitances of the memory chips 200 lying on the signal paths beyond the register buffer 300 invisible from the memory controller 30. Since the load capacitances of the signal paths that connect the memory controller 30 and the memory module 100 are reduced, it is possible to provide favorable signal quality even at a high data transfer rate.

While the memory system shown in FIG. 4 has only one memory slot 20 on the motherboard 10, an actual memory system may include a plurality (for example, four) of memory slots. A plurality of memory modules 100 are mounted on such memory slots, respectively. Mounting the memory modules 100 increases the load capacitances of the signal paths accordingly. In the present embodiment, the small load capacitance per memory module enables fast data transfer even with a plurality of memory modules mounted.

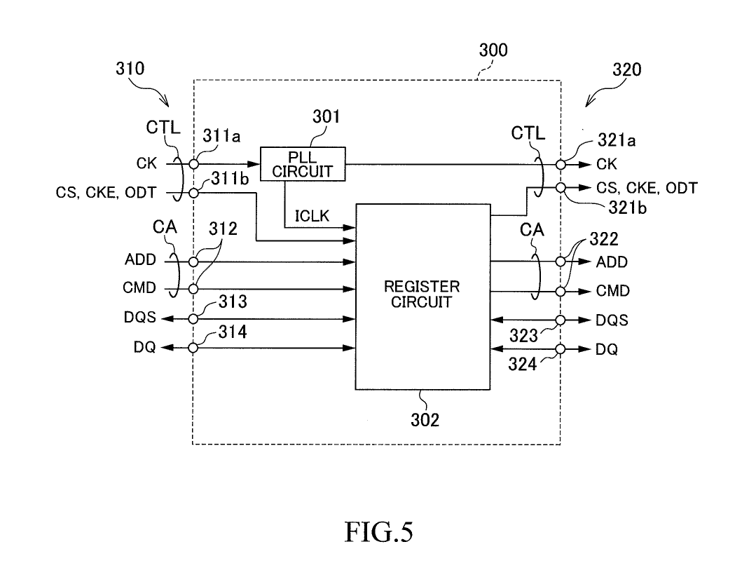

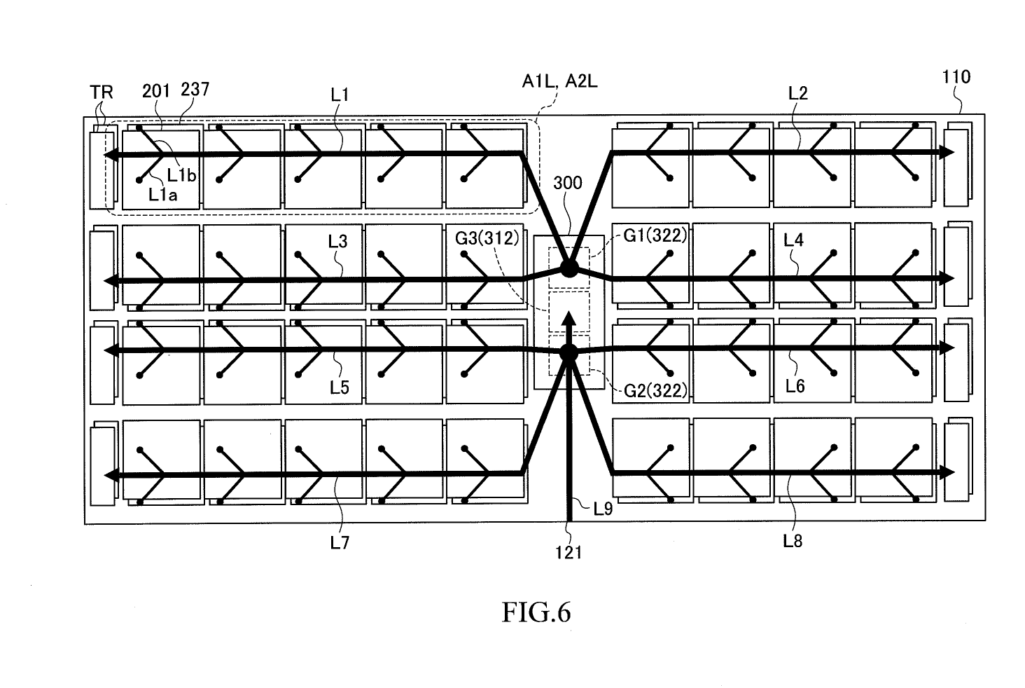

Turning to FIG. 5, the register buffer 300 includes controller side terminals 310 and memory chip side terminals 320. The controller side terminals 310 are terminals connected to the memory controller 30 on the motherboard 10. The controller side terminals 310 include: a clock input terminal 311a to which the clock signals CK are input; a control input terminal 311b to which the chip select signals CS, the clock enable signals CKE, and the on-die termination signals ODT are input; command address input terminals 312 to which the command address signals CA are input; a strobe input/output terminal 313 to/from which data strobe signals DQS are input/output; and a data input/output terminal 314 to/from which data (read data and write data) DQ is input/output. The memory chip side terminals 320 are terminals connected to the memory chips 200. The memory chip side terminals 320 include: a clock output terminal 321a from which the clock signals CK are output; a control output terminal 321b from which the chip select signals CS, the clock enable signals CKE, and the on-die termination signals ODT are output; command address output terminals 322 from which the command address signals CA are output; a strobe input/output terminal 323 to/from which the data strobe signals DQS are input/output; and a data input/output terminal 324 to/from which data (read data and write data) DQ is input/output. The data strobe signals DQS and the data DQ are transmitted and received to/from the memory controller 30 through the connectors 122 shown in FIG. 1. Although omitted in FIG. 5, the data strobe signals DQS are complementary signals including DQS and DQS#.

The clock signals CK input through the clock input terminal 311a are supplied to a PLL circuit 301. The PLL circuit 301 is a circuit that generates an internal clock signal ICLK based on the clock signals CK. The generated internal clock signal ICLK is supplied to a register circuit 302. The register circuit 302 is a circuit for buffering the chip select signals CS, the clock enable signals CKE, the on-die termination signals ODT, the command address signals CA, the data strobe signals DQS, and the data DQ. The register circuit 302 operates in synchronization with the internal clock signal ICLK.

Turning to FIG. 6, the command address signals CA input through the connectors 121 are supplied to the command address input terminals 312 of the register buffer 300 through a wiring L9 on the module substrate 110. The command address input terminals 312 are included in a group of terminals G3 formed on the register buffer 300. The group of terminals G3 is arranged between the group of terminals G1 and the group of terminals G2. The command address signals CA output from the command address output terminals 322 of the register buffer 300 are supplied to the memory chips 200 through the wirings L1 to L8. The wirings L1 to L8 have been described in detail with reference to FIG. 1.

Command address output terminals 322 connected to the wirings L1 to L4 are included in the group of terminals G1. Command address output terminals 322 connected to the wirings L5 to L8 are included in the group of terminals G2. In the present embodiment, the command address output terminals 322 included in the group of terminals G1 branch into the individual wirings L1 to L4 within the area of the group of terminals G1 when seen in a plan view. Similarly, the command address output terminals 322 included in the group of terminals G2 branch into the individual wiring L5 to L8 within the area of the group of terminals G2 when seen in a plan view. The wirings L1 to L4 branch off from the same contact plug. The wirings L5 to L8 branch off from the same contact plug. Details will be given later. Contact plugs refer to electrodes formed to penetrate through the module substrate 110.

Each of the wirings L1 to L8 is connected to the corresponding memory chips 200 through any of a plurality of wiring layers formed in the module substrate 110. Each of the wirings L1 to L8 branches off in an area sandwiched between a pair of memory chips 200 lying on the surface and back of the module substrate 110, and is connected to the memory chips 200 through branch wirings. For example, the wiring L1 branches off in the area sandwiched between the memory chips 201 and 237, and is connected to the memory chips 201 and 237 through branch wirings L1a and L1b. The wiring L1 branches into the branch wiring L1a and L1b from the same contact plug.

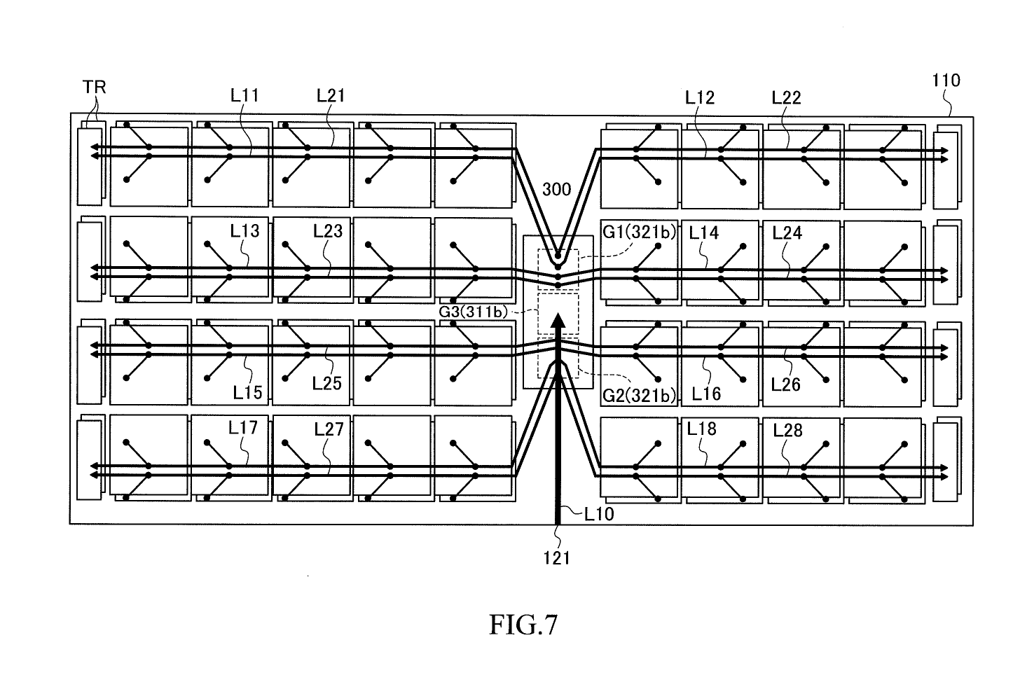

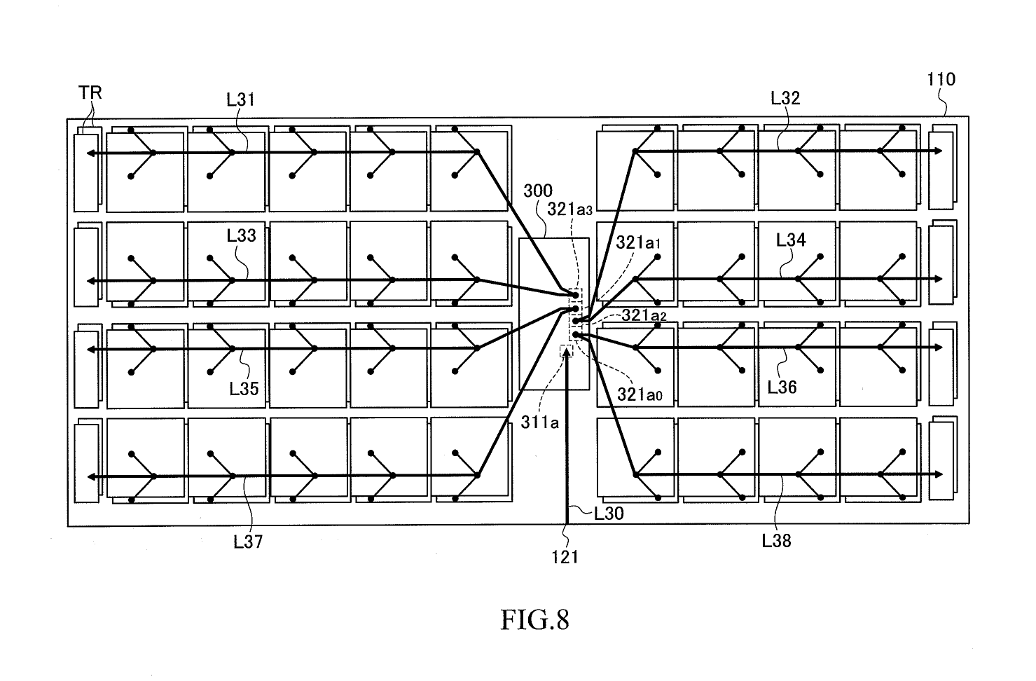

Turning to FIG. 7, it shows the flow of the chip select signals CS, the clock enable signals CKE, and the on-die termination signals ODT among the control signals CTL. The flow of the clock signals CK will be described later with reference to FIG. 8.

As shown in FIG. 7, the chip select signals CS, the clock enable signals CKE, and the on-die termination signals ODT input through the connectors 121 are supplied to the control input terminals 311b of the register buffer 300 through a wiring L10 on the module substrate 110. The control input terminals 311b are included in the group of terminals G3 formed on the register buffer 300. The chip select signals CS, the clock enable signals CKE, and the on-die termination signals ODT output from the control output terminals 321b of the register buffer 300 are supplied to the memory chips 200 through wirings L11 to L18 and L21 to L28.

The wirings L11 to L18 and L21 to L28 are separated for each Rank. Specifically, the wirings L11 and L12 are allocated to the memory chips 201 to 209 among the memory chips 200 belonging to the Rank 0. The wirings L15 and L16 are allocated to the memory chips 219 to 227. The wirings L11, L12, L15, and L16 transmit the chip select signal CS0#, the clock enable signal CKE0, and the on-die termination signal ODT0 corresponding to the Rank 0.

The wirings L21 and L22 are allocated to the memory chips 237 to 245 among the memory chips 200 belonging to the Rank 1. The wirings L25 and L26 are allocated to the memory chips 255 to 263. The wirings L21, L22, L25, and L26 transmit the chip select signal CS1# and the clock enable signal CKE1 corresponding to the Rank 1. In the present embodiment, no on-die termination signal ODT is supplied to the wirings L21, L22, L25, and L26.

The wirings L13 and L14 are allocated to the memory chips 210 to 218 among the memory chips 200 belonging to the Rank 2. The wirings L17 and L18 are allocated to the memory chips 228 to 236. The wirings L13, L14, L17, and L18 transmit the chip select signal CS2#, the clock enable signal CKE2, and the on-die termination signal ODT1 corresponding to the Rank 2.

The wirings L23 and L24 are allocated to the memory chips 246 to 254 among the memory chips 200 belonging to the Rank 3. The wirings L27 and L28 are allocated to the memory chips 264 to 272. The wirings L23, L24, L27, and L28 transmit the chip select signal CS3# and the clock enable signal CKE3 corresponding to the Rank 3. In the present embodiment, no on-die termination signal ODT is supplied to the wirings L23, L24, L27, and L28.

Among the control output terminals 321b, control output terminals 321b connected to the wirings L11 to L14, L21 to L24 are included in the group of terminals G1. Control output terminals 321b connected to the wirings L15 to L18, L25 to L28 are included in the group of terminals G2. Again, the wirings L11 to L18 and L21 to L28 are connected to the corresponding memory chips 200 through any of the plurality of wiring layers formed in the module substrate 110.

Turning to FIG. 8, the clock signals CK input through the connectors 121 are supplied to the clock input terminals 311a of the register buffer 300 through a wiring L30 on the module substrate 110. The clock signals CK output from the clock output terminals 321a of the register buffer 300 are supplied to the memory chips 200 through wirings L31 to L38.

The wirings L31 to L38 is separated for respective planar mounting areas of the corresponding memory chips 200. The connection relationship coincides with that of the foregoing wirings L1 to L8. Among the wirings L31 to L38, the wirings L31 and L33 are wirings for transmitting the clock signals CK3 and CK3#. The wiring L31 and L33s are connected to a clock output terminal 321a₃. The wirings L32 and L34 are wirings for transmitting the clock signals CK2 and CK2#. The wirings L32 and L34 are connected to a clock output terminal 321a₂. The wirings L35 and L37 are wirings for transmitting the clock signals CK1 and CK1#. The wirings L35 and L37 are connected to a clock output terminal 321a₁. The wirings L36 and L38 are wirings for transmitting the clock signals CK0 and CK0#. The wirings L36 and L38 are connected to a clock output terminal 321a₀. Again, the wirings L31 to L38 are connected to the corresponding memory chips 200 through any of the plurality of wiring layers formed in the module substrate 110.

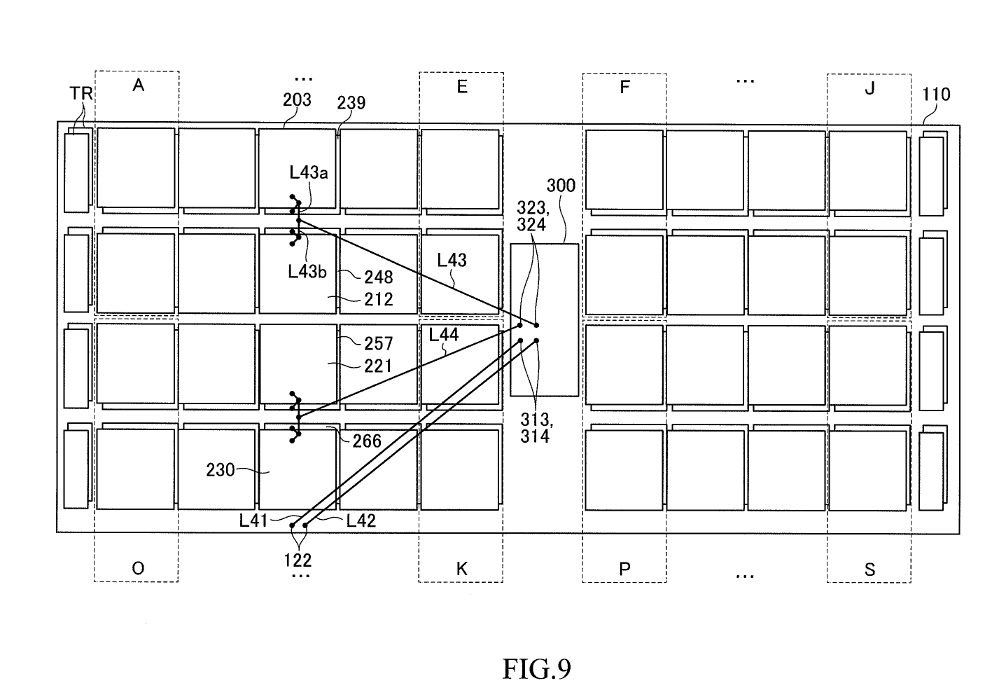

Turning to FIG. 9, it only shows extracted wirings relevant to one byte (eight bits) of data DQ corresponding to eight memory chips 203, 212, 221, 230, 239, 248, 257, and 266. Two pairs of data strobe signals DQS are allocated to one byte (eight bits) of data DQ.

As shown in FIG. 9, the connectors 122 are connected to the data input/output terminals 314 and strobe input/output terminals 313 of the register buffer 300 by wirings L41 and L42. The wiring L41 is intended to transmit four bits of data DQ and a pair of data strobe signals DQS corresponding to the memory chips 203, 212, 239, and 248. The wiring L42 is intended to transmit four bits of data DQ and a pair of data strobe signals DQS corresponding to the memory chips 221, 230, 257, and 266.

The memory chips 200 are connected to the data input/output terminals 324 and strobe input/output terminals 323 of the register buffer 300 by wirings L43 and L44. The wiring L43 is intended to transmit four bits of data DQ and a pair of data strobe signals DQS corresponding to the memory chips 203, 212, 239, and 248. The wiring L44 is intended to transmit four bits of data DQ and a pair of data strobe signals DQS corresponding to the memory chips 221, 230, 257, and 266.

The wiring L43 branches off in an area between the corresponding memory chips 203 and 239 and memory chips 212 and 248, into a branch wiring L43a intended for the memory chips 203 and 239 and a branch wiring L43b intended for the memory chips 212 and 248. The branch wiring L43a branches further in an area between the memory chips 203 and 239. The resulting branches are connected to the memory chips 203 and 239, respectively. Similarly, the branch wiring L43b branches further in an area between the memory chips 212 and 248. The resulting branches are connected to the memory chips 212 and 248, respectively. The wiring L44 branches off similarly, and is thereby connected to the memory chips 221, 230, 257, and 266.

As shown in FIG. 9, the 72 memory chips 201 to 272 are classified into 18 groups of four memory chips. In FIG. 9, the groups are denoted by alphabetical symbols A to S. Four memory chips constituting each group belong to respective different Ranks. The Ranks are exclusively selected based on the respective chip select signals CS. When a Rank is selected, one memory chip is activated in each of the 18 groups. That is, 18 memory chips 200 are simultaneously selected by a single access. Each memory chip 200 has four data input/output terminals. In consequence, 72 bits of data DQ are output from the memory module 100 or input to the memory module 100 by a single access.

In such a manner, data input/output terminals 324 formed on the register buffer 300 are connected to respective different input/output terminals of respective different memory chips mounted on the same memory chip mounting area. A data input/output terminal 324 formed on the register buffer 300 is connected in common to the corresponding data input/output terminals of a corresponding plurality of memory chips mounted on different memory chip mounting areas. Data input/output terminals 313 formed on the register buffer 300 are connected to respective different data input/output terminals of the connectors 122.

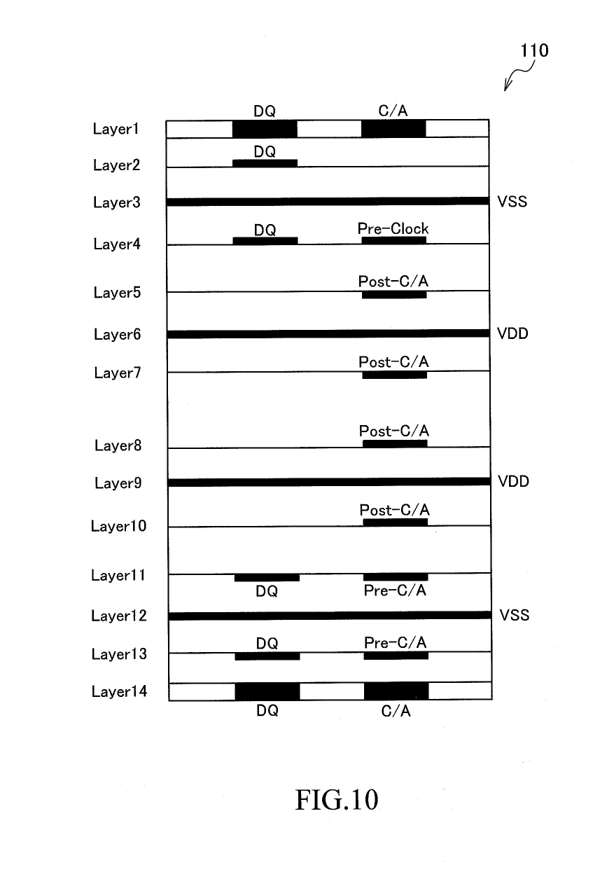

Turning to FIG. 10, the module substrate 110 of the present embodiment includes 14 wiring layers Layer1 to Layer14. The wiring layer Layer1 is located on the side of the memory chips 201 to 236. The wiring layer Layer14 is located on the side of the memory chips 237 to 272.

In the cross section shown in FIG. 10, the wirings (L1 to L8) for transmitting the command address signals CA are formed in the wiring layers Layer1, Layer5, Layer7, Layer8, Layer10, Layer11, Layer13, and Layer14. The wirings (L31 to L38) for transmitting the clocks signals CK are formed in the wiring layer Layer4. The wirings (L41 to L44) for transmitting data DQ are formed in the wiring layers Layer1, Layer2, Layer4, Layer11, Layer13, and Layer14. Although not shown in the cross section of FIG. 10, the wiring for transmitting the clock signals CK is also formed in the wiring layers Layer1, Layer13, and Layer14. In FIG. 10, signals with leading “Pre-” represent signals that are input to the register buffer 300. Signals with leading “Post-” represent signals that are output from the register buffer 300.

VSS wiring of large area is formed on the wiring layers Layer3 and Layer12. VDD wiring of large area is formed on the wiring layers Layer6 and Layer9. The VSS wiring is intended to supply a ground potential to the memory chips 200 and the register buffer 300. The VDD wiring is intended to supply a power supply potential to the memory chips 200 and the register buffer 300.

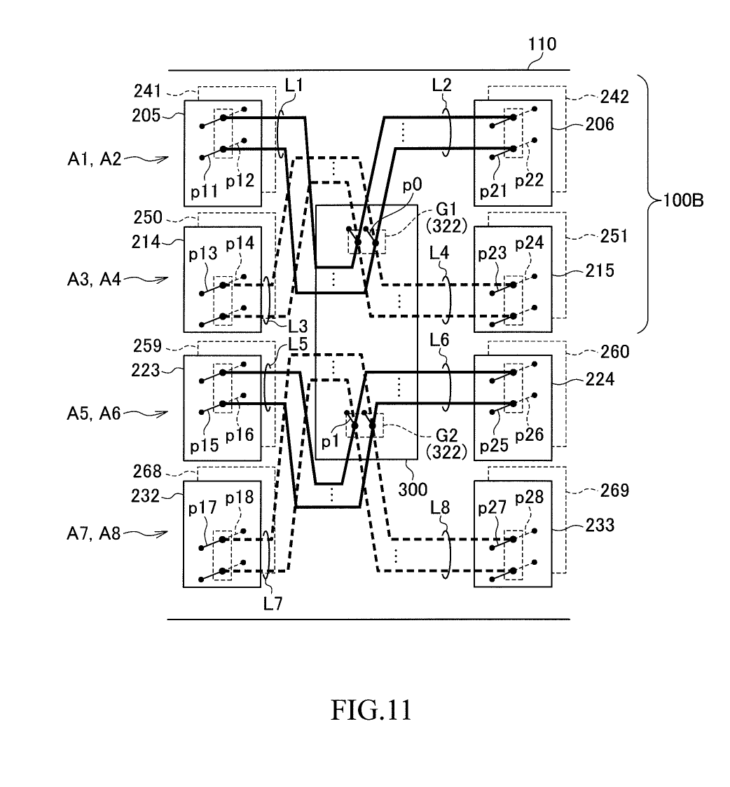

Turning to FIG. 11, it shows the wirings for transmitting half the command address signals CA, i.e., 11 bits. As has been described, the command address signals CA are signals of 22 bits in total. The 22 bits of command address signals CA will be denoted by CA1 to CA22. FIG. 11 shows the wirings for transmitting command address signals CA1 to CA11. In the present invention, command address output terminals 322 that output the command address signals CA1 to CA11 may be referred to as a “first group”. Similarly, command address input terminals that are formed on a memory chip 200 and intended to input the command address signals CA1 to CA11 may be referred to as a “first group”.

The wiring shown by solid lines in FIG. 11 represents the wirings L1 to L8 that are formed in the wiring layer Layer5. The wirings shown by broken lines represents the wirings L1 to L8 that are formed in the wiring layer Layer7. As shown in FIG. 11, the wirings L1 to L8 formed in the wiring layer Layer5 are connected to the memory chips belonging to the Ranks 0 and 1. The wirings L1 to L8 formed in the wiring layer Layer7 are connected to the memory chips belonging to the Ranks 2 and 3.

Description will be given in more detail. As shown by solid lines, the command address signals CA1 to CA11 that are output from the command address output terminals 322 included in the group of terminals G1 of the register buffer 300 are supplied to the memory chips 201 to 209 (FIG. 11 shows only the memory chips 205 and 206) that are mounted on the memory chip mounting area A1 and belong to the Rank 0, through a wiring p0, the wirings L1 and L2, and wirings p11 and p21. The command address signals CA1 to CA11 are also supplied to the memory chips 237 to 245 (FIG. 11 shows only the memory chips 241 and 242) that are mounted on the memory chip mounting area A2 and belong to the Rank 1, through wiring p12 and p22. As shown by broken lines, the command address signals CA1 to CA11 are further supplied to the memory chips 210 to 218 (FIG. 11 shows only the memory chips 214 and 215) that are mounted on the memory chip mounting area A3 and belong to the Rank 2, through the wiring p0, the wirings L3 and L4, and wirings p13 and p23. The command address signals CA1 to CA11 are also supplied to the memory chips 246 to 254 (FIG. 11 shows only the memory chips 250 and 251) that are mounted on the memory chip mounting area A4 and belong to the Rank 3, through wirings p14 and p24.

As shown by solid lines, the command address signals CA1 to CA11 that are output from the command address output terminals 322 included in the group of terminals G2 of the register buffer 300 are supplied to the memory chips 219 to 227 (FIG. 11 shows only the memory chips 223 and 224) that are mounted on the memory chip mounting area A5 and belong to the Rank 0, through a wiring p1, the wirings L5 and L6, and wirings p15 and p25. The command address signals CA1 to CA11 are also supplied to the memory chips 255 to 263 (FIG. 11 shows only the memory chips 259 and 260) that are mounted on the memory chip mounting area A6 and belong to the Rank 1, through wirings p16 and p26. As shown by broken lines, the command address signals CA1 to CAll are further supplied to the memory chips 228 to 236 (FIG. 11 shows only the memory chips 232 and 233) that are mounted on the memory chip mounting area A7 and belong to the Rank 2, through the wiring p1, the wirings L7 and L8, and wirings p17 and p27. The command address signals CA1 to CA11 are also supplied to the memory chips 264 to 272 (FIG. 11 shows only the memory chips 268 and 269) that are mounted on the memory chip mounting area A8 and belong to the Rank 3, through wirings p18 and p28.

As shown in FIG. 11, the wiring L1 is configured so that it is led out from the command address output terminals 322 to the side of the memory chip mounting area A3 before bent and extended to the left portion A1L, of the memory chip mounting area A1. The wiring L3 is configured so that it is led out from the command address output terminals 322 to the side of the memory chip mounting area A1 before bent and extended to the left portion A3L of the memory chip mounting area A3. The wirings L5 and L7 have a similar configuration. On the other hand, the wirings L2, L4, L6, and L8 have no such bent shape. The reason is that the command address output terminals 322 on the register buffer 300 are laid out primarily in the X direction while the command address input terminals on the memory chips 200 are laid out primarily in the Y direction.

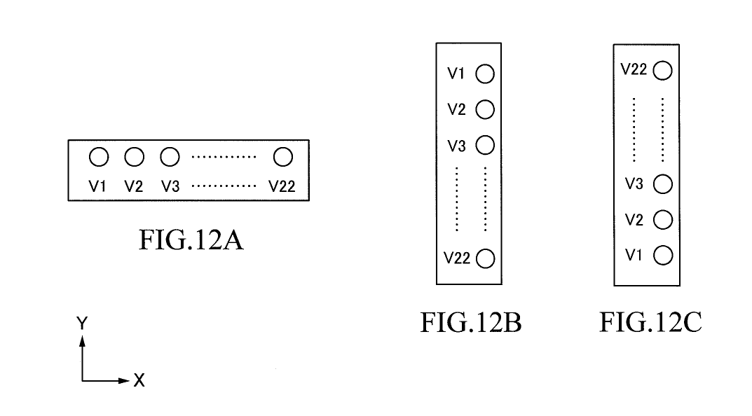

Turning to FIGS. 12A to 12C, they each are a schematic diagram and thus differ from an actual terminal layout. The actual terminal layout will be described later.

As shown in FIG. 12A, terminals that output the 22 bits of command address signals CA1 to CA22 will be denoted by V1 to V22, respectively. On the register buffer 300, the terminals V1 to V22 are arranged in the X direction. As shown in FIGS. 12B and 12C, terminals that input the 22 bits of command address signals CA1 to CA22 will be denoted by V1 to V22, respectively. On memory chips 200, the terminals V1 to V22 are arranged in the Y direction.

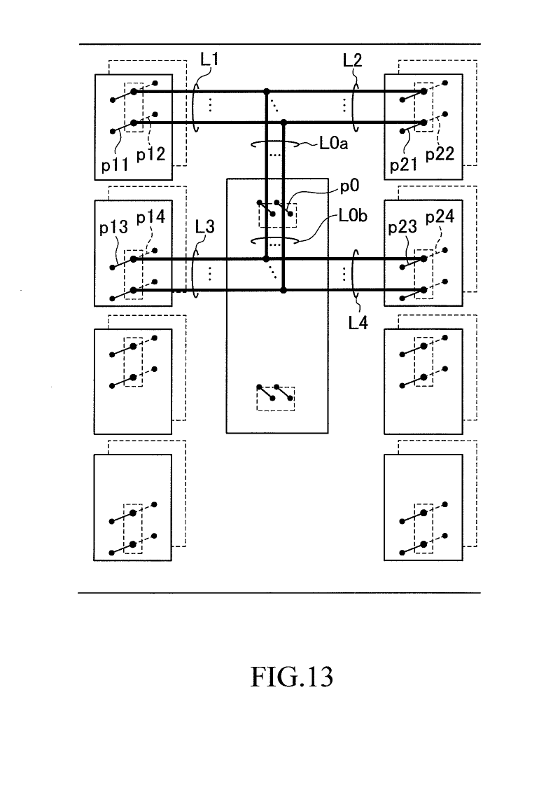

Suppose, for example, that the command address signals CA1 to CA22 are supplied to the memory chips 200 by using only a single wiring layer. In such a case, as shown in FIG. 13, the command address signals CA1 to CA22 are led out from the command address output terminals 322 through the wiring p0 and passed through a wiring L0a before branched into the wirings L1 and L2. The command address signals CA1 to CA22 are also passed through a wiring L0b before branched into the wirings L3 and L4. Such a layout not only results in a high wiring density and high line capacitance, but also produces branch points in the middle of wiring which function as a stub. This can cause degradation of signal quality.

To solve such a problem, the present embodiment uses two wiring layers Layer5 and Layer7 to transmit the command address signals CA1 to CA11, and employs the layout of bending the wirings L1, L3, L5, and L7. As shown in FIGS. 12B and 12C, the order of arrangement of the terminals V1 to V22 in the Ranks 0 and 1 is reverse to that in the Ranks 2 and 3. This allows a single-stroke layout of the wirings L1 to L8 without a stub, thereby preventing degradation of signal quality.

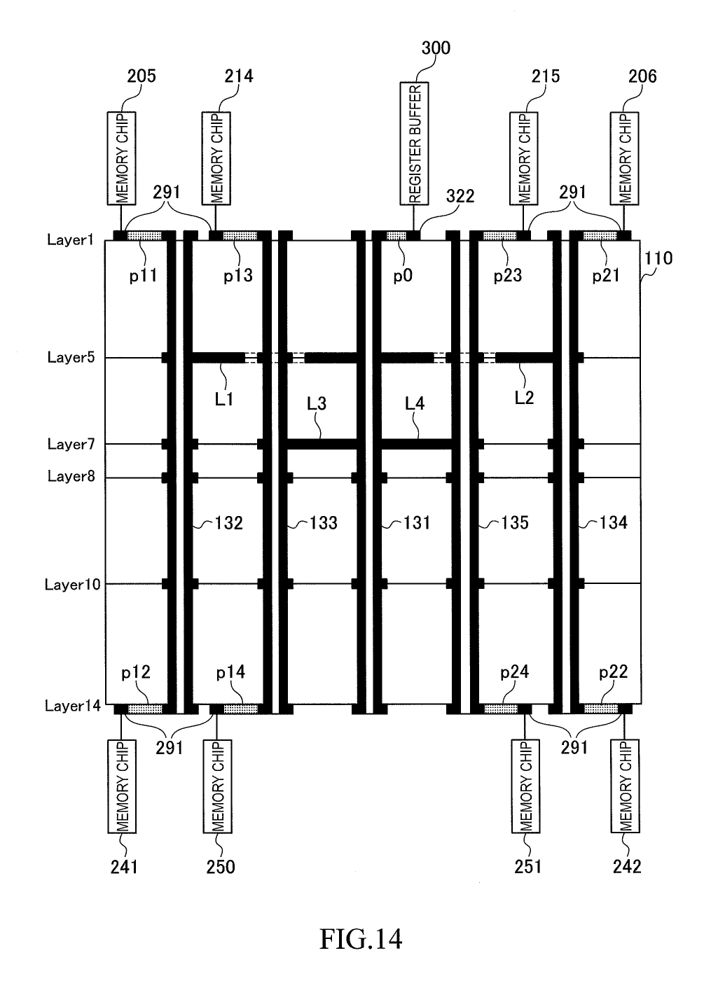

Turning to FIG. 14, the module substrate 110 includes a plurality of contact plugs 131 to 135 formed to penetrate through the plurality of wiring layers. The contact plug 131 is connected to a command address output terminal 322 of the register buffer 300 through the wiring p0 which is formed in the wiring layer Layer1. Contact plugs formed in the module substrate 110 are classified into at least first to fourth groups. The contact plug 131 belongs to the first group. The contact plugs 132 to 135 belong to the third group.

The contact plug 132 is connected to a command address input terminal 291 of the memory chip 205 through the wiring p11 which is formed in the wiring layer Layer1. The contact plug 132 is also connected to a command address input terminal 291 of the memory chip 241 through the wiring p12 which is formed in the wiring layer Layer14. The contact plug 133 is connected to a command address input terminal 291 of the memory chip 214 through the wiring p13 which is formed in the wiring layer Layer1. The contact plug 133 is also connected to a command address input terminal 291 of the memory chip 250 through the wiring p14 which is formed in the wiring layer Layer14.

The contact plug 134 is connected to a command address input terminal 291 of the memory chip 206 through the wiring p21 which is formed in the wiring layer Layer1. The contact plug 134 is also connected to a command address input terminal 291 of the memory chip 242 through the wiring p22 which is formed in the wiring layer Layer14. The contact plug 135 is connected to a command address input terminal 291 of the memory chip 215 through the wiring p23 which is formed in the wiring layer Layer1. The contact plug 135 is also connected to a command address input terminal 291 of the memory chip 251 through the wiring p24 which is formed in the wiring layer Layer14.

As shown in FIG. 14, the contact plug 131 is connected to the contact plugs 132 and 134 through the wirings L1 and L2 that is formed in the wiring layer Layer5. The contact plug 131 is also connected to the contact plugs 133 and 135 through the wirings L3 and L4 that is formed in the wiring layer Layer7. As a result, the command address output terminal 322 of the register buffer 300 is connected to the command address input terminals 291 of the respective memory chips 200. In such a manner, the command address signals CA1 to CA11 are supplied to the memory chips 200 in common.

In the present embodiment, the wirings L1 to L8 branch off at contact plugs. In the example shown in FIG. 14, all the four branches into the wirings L1 to L4 originate from the contact plug 131. This minimizes deterioration of signal quality due to branching.

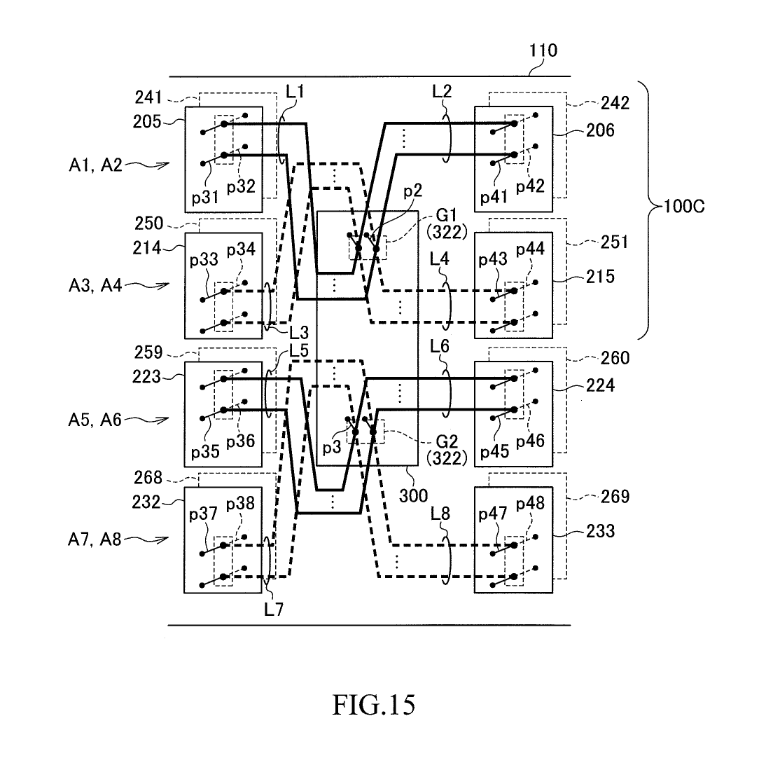

Turning to FIG. 15, it shows wirings for transmitting the command address signals CA12 to CA22 among the 22 bits of command address signals CA1 to CA22. In the present invention, command address output terminals 322 that output the command address signals CA12 to CA22 may be referred to as a “second group.” Similarly, command address input terminals that are formed on a memory chip 200 and intended to input the command address signals CA12 to CA22 may be referred to as a “second group.”

The wirings shown by solid lines in FIG. 15 represents the wirings L1 to L8 that is formed in the wiring layer Layer8. The wiring shown by broken lines represents the wirings L1 to L8 that is formed in the wiring layer Layer10. As with the command address signals CA1 to CA11 shown in FIG. 11, the wirings L1 to L8 formed in the wiring layer Layer8 are connected to memory chips that belong to the Ranks 0 and 1. The wirings L1 to L8 formed in the wiring layer Layer10 are connected to memory chips that belong to the Ranks 2 and 3. The connection relationship between the wirings and the routing of the wiring are the same as with the command address signals CA1 to CA11 shown in FIG. 11. Redundant description will thus be omitted.

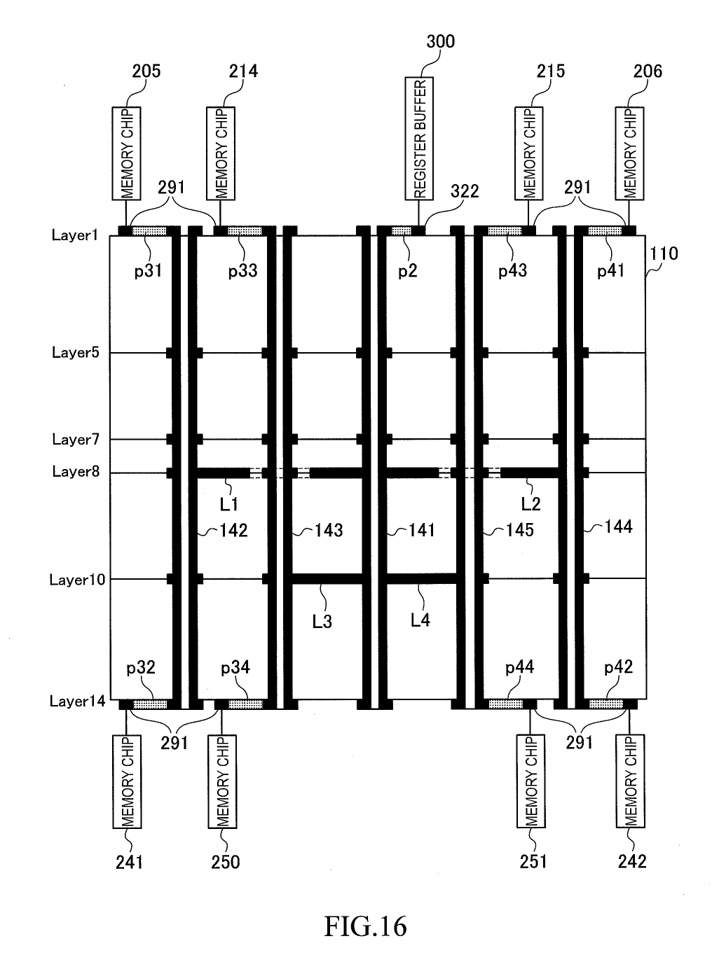

Turning to FIG. 16, the module substrate 110 further includes a plurality of contact plugs 141 to 145. The contact plug 141 is connected to a command address output terminal 322 of the register buffer 300 through the wiring p2 which is formed in the wiring layer Layer1. The contact plug 141 belongs to the second group. The contact plugs 142 to 145 belong to the fourth group.

The contact plug 142 is connected to a command address input terminal 291 of the memory chip 205 through a wiring p31 which is formed in the wiring layer Layer1. The contact plug 142 is also connected to a command address input terminal 291 of the memory chip 241 through a wiring p32 which is formed in the wiring layer Layer14. The contact plug 143 is connected to a command address input terminal 291 of the memory chip 214 through a wiring p33 which is formed in the wiring layer Layer1. The contact plug 143 is also connected to a command address input terminal 291 of the memory chip 250 through a wiring p34 which is formed in the wiring layer Layer14.

The contact plug 144 is connected to a command address input terminal 291 of the memory chip 206 through a wiring p41 which is formed in the wiring layer Layer1. The contact plug 144 is also connected to a command address input terminal 291 of the memory chip 242 through a wiring p42 which is formed in the wiring layer Layer14. The contact plug 145 is connected to a command address input terminal 291 of the memory chip 215 through a wiring p43 which is formed in the wiring layer Layer1. The contact plug 145 is also connected to a command address input terminal 291 of the memory chip 251 through a wiring p44 which is formed in the wiring layer Layer14.

As shown in FIG. 16, the contact plug 141 is connected to the contact plugs 142 and 144 through the wirings L1 and L2 that is formed in the wiring layer Layer8. The contact plug 141 is also connected to the contact plugs 143 and 145 through the wirings L3 and L4 that is formed in the wiring layer Layer10. As a result, the command address output terminal 322 of the register buffer 300 is connected to the command address input terminals 291 of the respective memory chips 200. In such a manner, the command address signals CA12 to CA22 are supplied to the memory chips 200 in common.

As described above, in the present embodiment, the command address signals CA1 to CA11 output from the first group of command address output terminals 322 are supplied to memory chips 200 through the wiring layer Layer5 or Layer7. The command address signals CA12 to CA22 output from the second group of command address output terminals 322 are supplied to memory chips 200 through the wiring layer Layer8 or Layer10. Since the command address signals CA1 to CA22 from the single register buffer 300 are transmitted and supplied to each single memory chip 200 by using two wiring layers, the wiring densities of the wiring layers can be lowered to reduce line capacitance. Such a configuration also improves the degree of freedom of wiring, allowing a reduction in design cost.

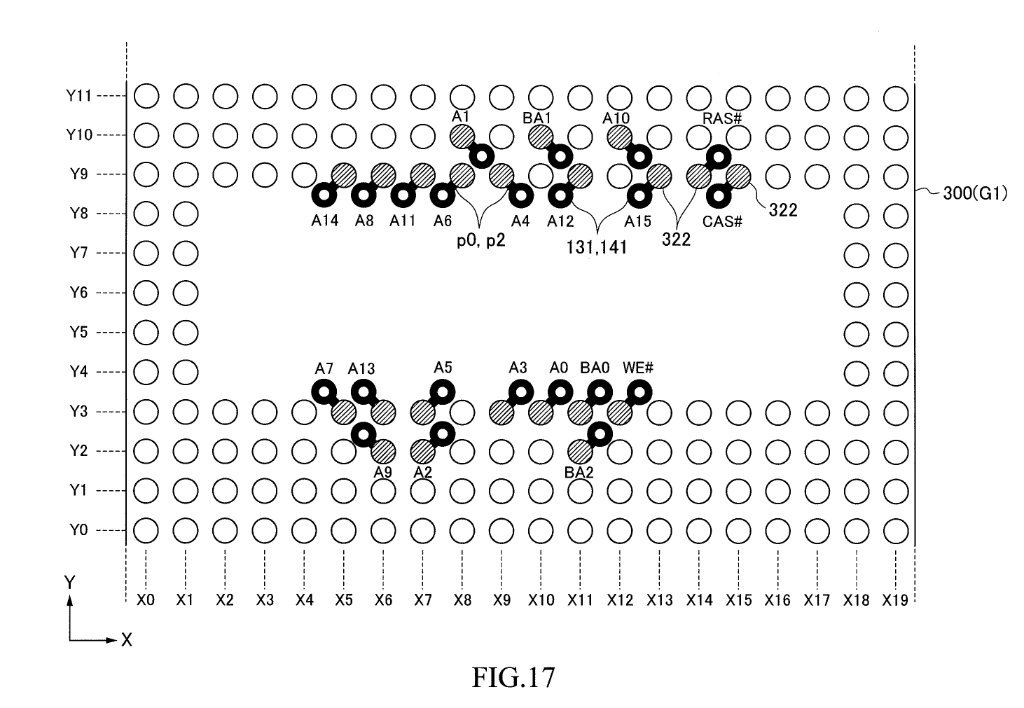

Turning to FIG. 17, the group of terminals G1 formed on the register buffer 300 includes a plurality of terminals that are arranged at the intersections of X coordinates X0 to X19 and Y coordinates Y0 to Y11. Note that no terminal is arranged at the intersections of X coordinates X2 to X17 and Y coordinates Y4 to Y8. In FIG. 17, terminals are shown by circles. Hatched ones represent command address output terminals 322. The elements obliquely extended from the command address output terminals 322 constitute the wirings p0 and p2 formed in the wiring layer Layer1 (see FIGS. 14 and 16). The double-circled elements in connection with the wirings p0 and p2 are contact plugs 131 and 141 which are formed to penetrate through the module substrate 110 (see FIGS. 14 and 16). Since the command address output terminals 322 formed on the register buffer 300 are connected to the contact plugs 131 and 141 lying in their immediate vicinities, the wirings p0 and p2 have an extremely small wiring length, which hardly affects signal characteristics.

As shown in FIG. 17, the command address output terminals 322 are arranged in the X direction at Y coordinates of Y2, Y3, Y9, and Y10. For example, terminals that output address signals A14, A8, and All are arranged in the X direction at a Y coordinate of Y9. Terminals that output address signals A7, A13, and A5 are arranged in the X direction at a Y coordinate of Y3. Of these, the terminals that output the address signals A14 and A7 both have an X coordinate of X5. The terminals that output the address signals A8 and A13 both have an X coordinate of X6. The terminals that output the address signals A11 and A5 both have an X coordinate of X7.

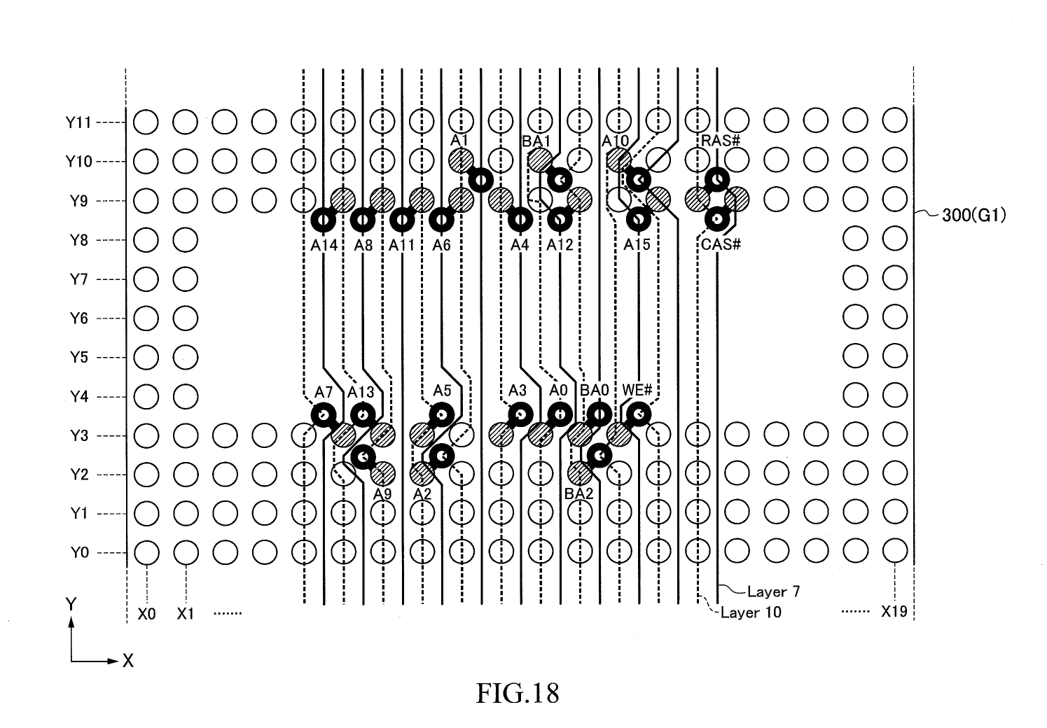

Turning to FIG. 18, directly below the register buffer 300, the wirings L3 and L4 formed in the wiring layers Layer7 and Layer10 extend in the Y direction. The solid lines in FIG. 18 represent the wirings L3 and L4 that are formed in the wiring layer Layer7. The broken lines represent the wirings L3 and L4 that are formed in the wiring layer Layer10. In the example shown in FIG. 18, the terminals that output the address signals A14, A8, and All, arranged at a Y coordinate of Y9, are connected to the wirings L3 and L4 (solid lines) formed in the wiring layer Layer7. The terminals that output the address signals A7, A13, and A5, arranged at a Y coordinate of Y3, are connected to the wirings L3 and L4 (broken lines) formed in the wiring layer Layer10. Although the X coordinates of the terminals that output the address signals A14, A8, and All and those of the terminals that output the address signals A7, A13, and A5 coincide with each other (X5, X6, and X7), respectively, the wiring pitch of the wirings L3 and L4 in the X direction can be made equivalent to the arrangement pitch of the command address terminals 322 in the X direction. This can reduce line capacitance as compared to when such wiring is formed in a single wiring layer.

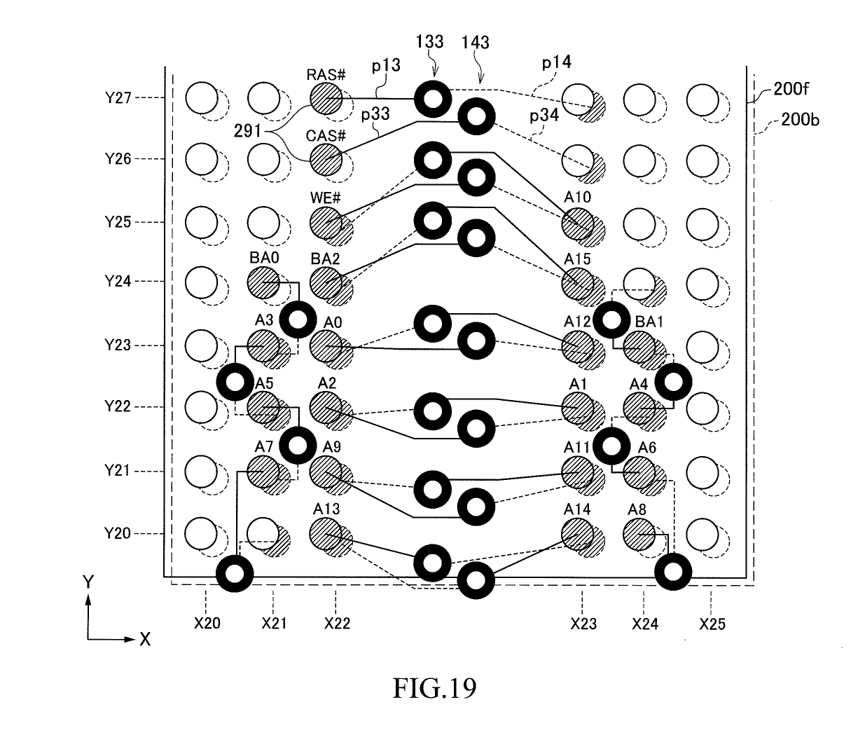

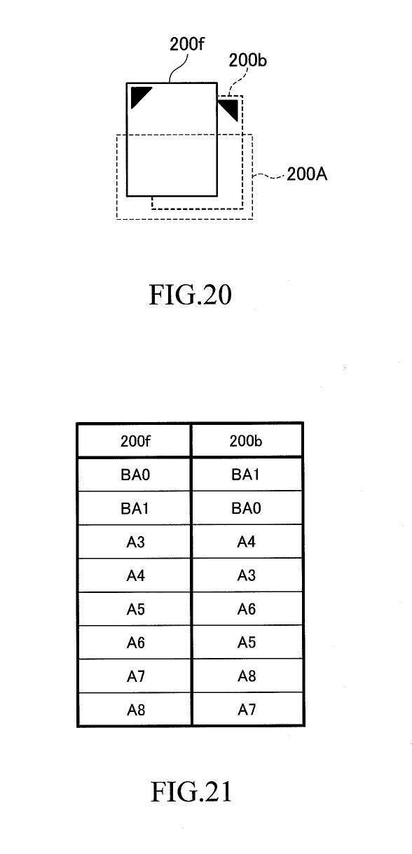

Turning to FIG. 19, it is an enlarged view of an area 200A shown in FIG. 20. In FIGS. 19 and 20, a memory chip 200 that is mounted on the surface side of the module substrate 110 will be denoted by 200f. A memory chip 200 that is mounted on the back side of the module substrate 110 will be denoted by 200b. In FIG. 20, the triangle marks on the memory chips 200f and 200b indicate the same corners of the respective memory chips 200f and 200b. That is, the memory chips 200f and 200b are mounted on the module substrate 110 in reverse positions.

As shown in FIG. 19, command address input terminals 291 formed on the memory chips 200 include a plurality of terminals that are arranged at the intersections of X coordinates X21 to X24 and Y coordinates Y20 to Y27. In FIG. 19, terminals are shown by circles. Hatched ones represent command address input terminals 291. FIG. 19 shows a pair of memory chips 200 that are arranged on the surface and back of the module substrate 110. The pair of memory chips 200 have terminals in the same planer positions, i.e., at the same X coordinates and Y coordinates. For better viewability, FIG. 19 shows the terminals lying on the surface and back of the module substrate 110 in staggered planar positions.

The elements pulled out from the command address input terminals 291 in solid lines constitute the wirings p13, p33, and the like formed in the wiring layer Layer1 (see FIGS. 14 and 16). The elements pulled out from the command address input terminals 291 in broken lines constitute the wirings p14, p34, and the like formed in the wiring layer Layer14 (see FIGS. 14 and 16). The double-circled elements in connection with the wirings p13, p14, p33, p34, and the like are contact plugs 133, 143, and the like formed to penetrate through the module substrate 110 (see FIGS. 14 and 16). As shown in FIG. 19, the interval between the coordinates X22 and X23 is wider, in which space a lot of contact plugs 133, 143, and the like are arranged. As shown in FIG. 19, a plurality of the contact plugs 133 and a plurality of the contact plugs 143 both are arranged in the Y direction and adjoin each other in the X direction. The plurality of contact plugs 133 have respective Y coordinates different from those of the plurality of contact plugs 143. This prevents interference between the contact plugs. Again, since the command address input terminals 291 formed on a memory chip 200 are connected to contact plugs 133 and 143 lying in their immediate vicinities, the wiring p13 and the like have an extremely small wiring length, which hardly affects signal characteristics.

The memory chip mounted on the surface side of the module substrate 110 is denoted by 200f, and the memory chip mounted on the back side of the module substrate 110 by 200b. As shown in FIG. 19, the same command address input terminals 291 as those arranged at an X coordinate of X22 on the memory chip 200f (RAS# to A13) are arranged at an X coordinate of X23 on the memory chip 200b. Similarly, the same command address input terminals 291 as those arranged at an X coordinate of X23 on the memory chip 200f (A10 to A14) are arranged at an X coordinate of X22 on the memory chip 200b. This means that the arrangement of such terminals is unchanged between the memory chips 200f and 200b since the memory chips 200f and 200b are mounted on the module substrate 110 in reverse positions.

On the other hand, the same command address input terminals 291 as those arranged at an X coordinate of X21 on the memory chip 200f (BA0 to A7) are arranged at the same X coordinate X22 on the memory chip 200b. Similarly, the same command address input terminals 291 as those arranged at an X coordinate of X24 on the memory chip 200f (BA1 to A8) are arranged at the same X coordinate X24 on the memory chip 200b. This means that the memory chips 200f and 200b are mirrored in terms of the arrangement of those terminals. Turning to FIG. 21, it is a table describing the correspondence between the mirrored terminals.

Note that the mirroring is not complete, and the terminals are arranged with a shift of one pitch in the Y coordinate as shown in FIG. 19. Specifically, the command address input terminals 291 arranged at an X coordinate of X21 on the memory chip 200f (BA0 to A7) have Y coordinates of Y24 to Y21, respectively. The same terminals appear at Y coordinates of Y23 to Y20 on the memory chip 200b. Similarly, the command address input terminals 291 arranged at an X coordinate of X24 on the memory chip 200f (BA1 to A8) have Y coordinates of Y23 to Y20, respectively. The same terminals appear at Y coordinates of Y24 to Y21 on the memory chip 200b. Such arrangement increases the degree of freedom in the layout of the wiring p11 and the like.

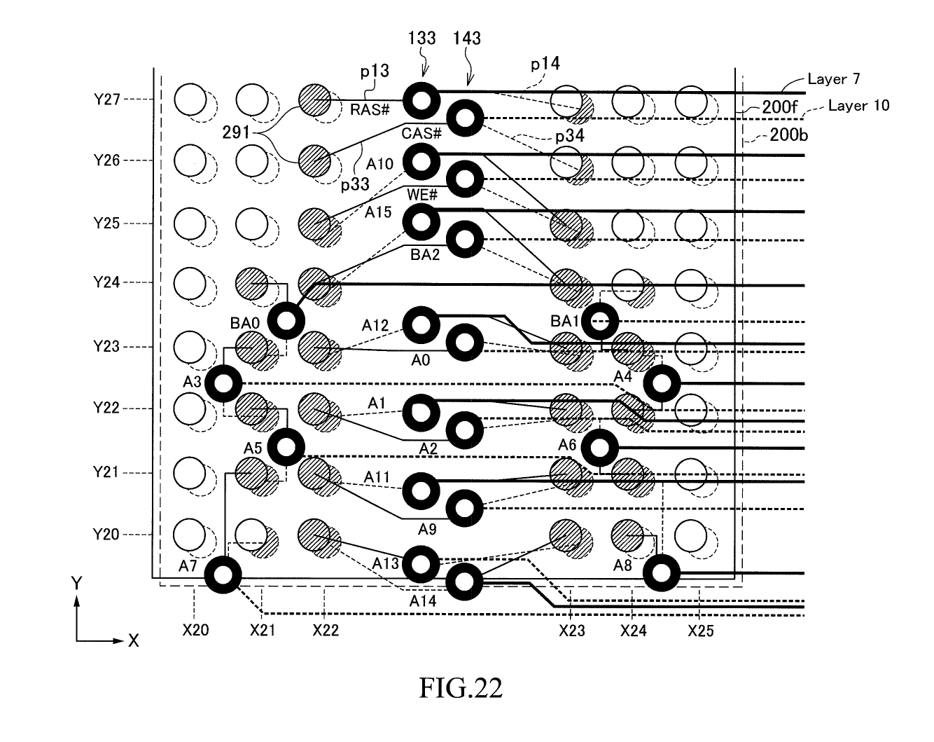

Turning to FIG. 22, directly below a memory chip 200, the wirings L3 and L4 formed in the wiring layers Layer7 and Layer10 extends in the X direction. The solid lines in FIG. 22 represent wirings L3 and L4 that is formed in the wiring layer Layer7. The broken lines represent wirings L3 and L4 that is formed in the wiring layer Layer10. The use of two wiring layers makes it possible to make the wiring pitch of the wirings L3 and L4 in the Y direction equivalent to the arrangement pitch of the command address input terminals 291 in the Y direction. This can reduce line capacitance as compared to when such wirings are formed in a single wiring layer.

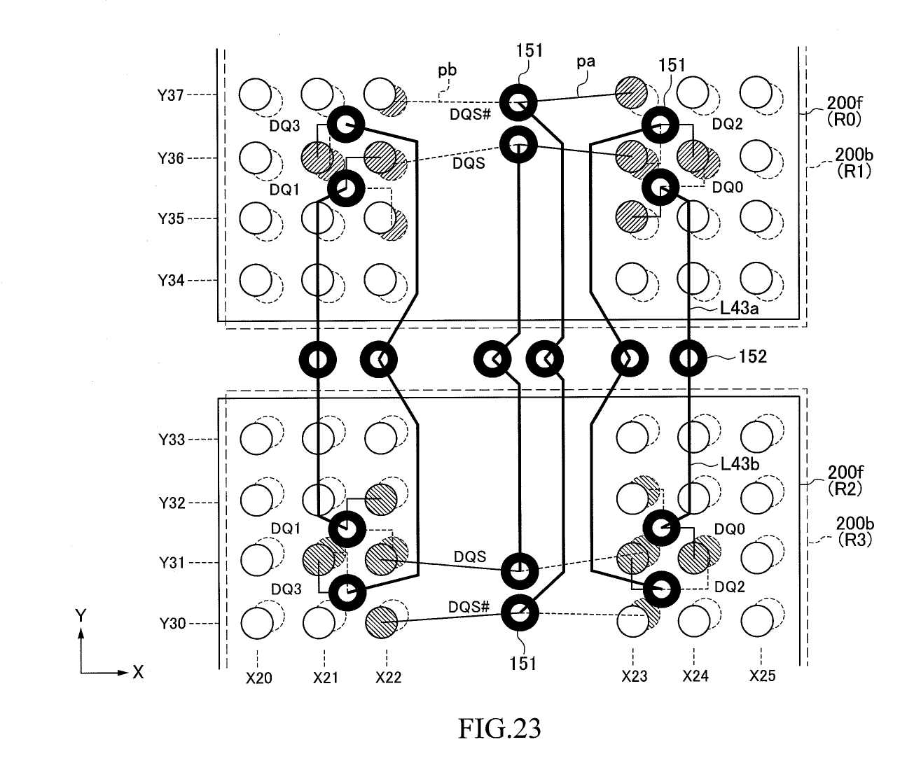

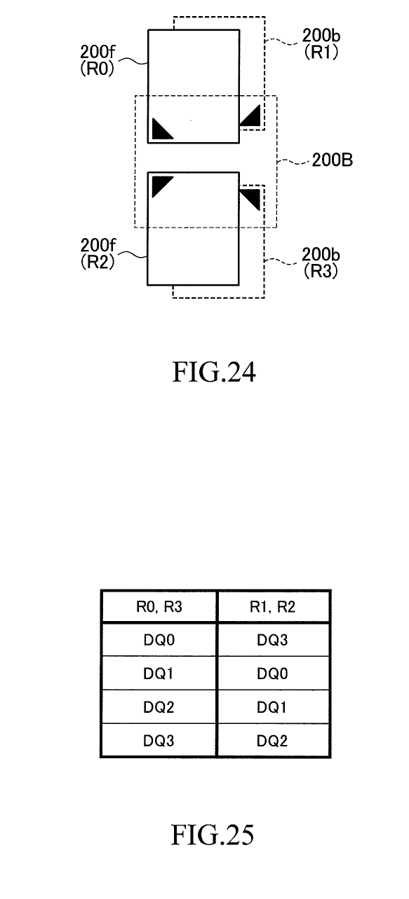

Turning to FIG. 23, it is an enlarged view of an area 200B shown in FIG. 24. In FIG. 24, the triangle marks on the memory chips 200f and 200b have the same meaning as described above. More specifically, the memory chip 200 belonging to the Rank 0 and the memory chip 200 belonging to the Rank 2 are placed in 180° different directions. Similarly, the memory chip 200 belonging to the Rank 2 and the memory chip 200 belonging to the Rank 3 are placed in 180° different directions.

As shown in FIG. 23, data input/output terminals 292 formed on the memory chips 200 include a plurality of terminals that are arranged at the intersections of X coordinates X21 to X24 and Y coordinates Y30 to Y37. In FIG. 23, terminals are shown by circles. Hatched ones represent data input/output terminals 292.

Elements pa extended from data input/output terminals 292 in solid lines constitute data wirings that are formed in the wiring layer Layer1. Elements pb extended from data input/output terminals 292 in broken lines constitute data wirings that are formed in the wiring layer Layer14. The double-circled elements in connection with such data wirings are contact plugs 151 which are formed to penetrate through the module substrate 110. As shown in FIG. 23, contact plugs intended for data strobe signals DQS and DQS# are arranged in the space between the coordinates X22 and X23. Contact plugs for data DQ0 and DQ2 are arranged between the coordinates X23 and X24. Contact plugs for data DQ1 and DQ3 are arranged between the coordinates X21 and X22.

There are contact plugs 152 between the coordinates Y33 and Y34, i.e., in the space between the memory chips 200 belonging to the Ranks 0 and 1 and the memory chips 200 belonging to the Ranks 2 and 3. Data wirings that connect the contact plugs 151 and the contact plugs 152 corresponds to branch wirings L43a and L43b shown in FIG. 9.

The memory chips 200 belonging to the Ranks 0 to 3 will be referred to as “memory chips R0 to R3,” respectively. The data input/output terminals 292 intended for data DQ0 to DQ3 will be referred to as “terminals DQ0 to DQ3,” respectively. As shown in FIG. 23, the terminal DQ0 of the memory chip R0 is arranged at the intersection of coordinates X23 and Y35. The terminal DQ0 of the memory chip R1 is arranged at the intersection of coordinates X24 and Y36. When seen in a plan view, the terminals DQ0 are arranged in different positions, but with a shift of only one pitch both in the X direction and in the Y direction. The terminal DQ1 of the memory chip R0 is arranged at the intersection of coordinates X22 and Y36. The terminal DQ1 of the memory chip R1 is arranged at the intersection of coordinates X22 and Y35. When seen in a plan view, the terminals DQ1 are arranged in different positions, but with a shift of only one pitch in the Y direction. The terminal DQ2 of the memory chip R0 is arranged at the intersection of coordinates X24 and Y36. The terminal DQ2 of the memory chip R1 is arranged at the intersection of coordinates X23 and Y36. When seen in a plan view, the terminals DQ2 are arranged in different positions, but with a shift of only one pitch in the X direction. Both the terminals DQ3 of the memory chips R0 and R1 are arranged at the intersection of coordinates X21 and Y36, i.e., arranged in the same position when seen in a plan view.

The terminals DQ0 to DQ3 of the memory chips R2 and R3 have the same layout as that of the terminals DQ0 to DQ3 of the memory chips R0 and R1. The memory chips R0 and R1 are mirrored each other, and the memory chips R2 and R3 are mirrored each other, in terms of the arrangement of the foregoing terminals DQ0 to DQ3. FIG. 25 is a table describing the correspondence between the mirrored terminals DQ0 to DQ3.

Note that the mirroring is not complete. As described above, the terminals DQ0 are arranged with a shift of one pitch both in the X direction and in the Y direction. The terminals DQ1 are arranged with a shift of one pitch in the Y direction. The terminals DQ2 are arranged with a shift of one pitch in the X direction. The terminals DQ3 are in the same planar positions. The terminals DQ0 to DQ3, DQS, and DQS# formed on the memory chips R0 and R2 are mirrored in the Y direction. Similarly, the terminals DQ0 to DQ3, DQS, and DQS# formed on the memory chips R1 and R3 are mirrored in the Y direction. Such an arrangement can make the transmission conditions of the data DQ0 to DQ3 and the strobe signals DQS and DQS# almost uniform among the memory chips R0 to R3.

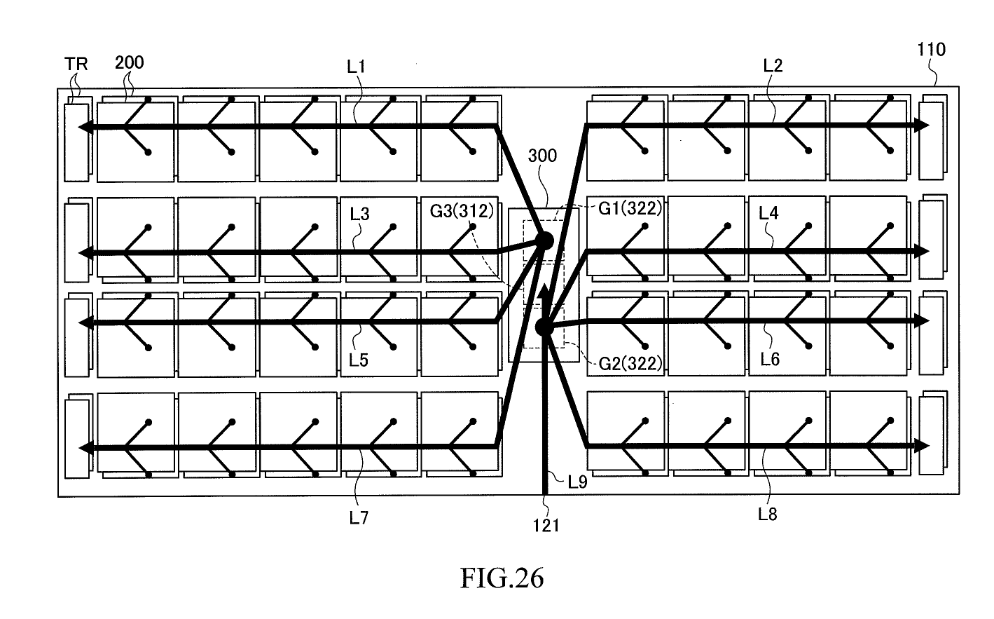

Turning to FIG. 26, command address output terminals 322 that are connected to the wirings L1, L3, L5, and L7 are included in the group of terminals G1. Command address output terminals 322 that are connected to the wirings L2, L4, L6, and L8 are included in the group of terminals G2. According to the present example, command address signals CA output from the group of terminals G1 are supplied to the wirings L1, L3, L5, and L7 which have the same loads. This makes the command address signals CA on the wirings L1, L3, L5, and L7 uniform in signal quality. Similarly, command address signals CA output from the group of terminals G2 are supplied to the wirings L2, L4, L6, and L8 which have the same loads. This makes the command address signals CA on the wirings L2, L4, L6, and L8 uniform in signal quality. Note that, in the present example, the loads on the command address output terminals 322 included in the group of terminals G1 are different from those on the command address output terminals 322 included in the group of terminals G2. It is therefore preferred to use output drivers of different power. In contrast, in the case shown in FIG. 6, output drivers of the same power may be used.

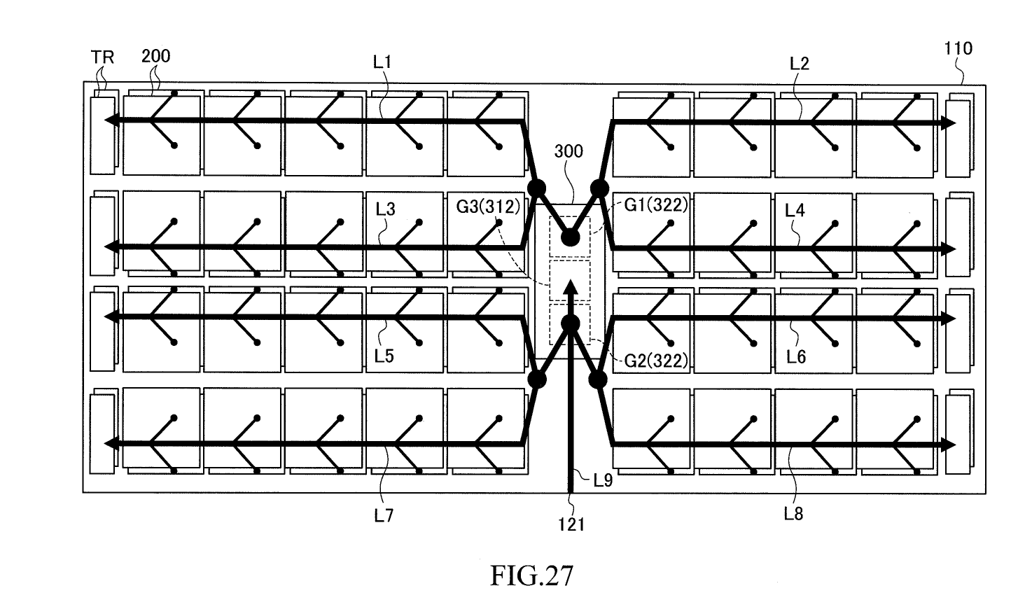

Turning to FIG. 27, like FIG. 6, command address output terminals 322 that are connected to the wirings L1 to L4 are included in the group of terminals G1. Command address output terminals 322 that are connected to the wirings L5 to L8 are included in the group of terminals G2. Unlike the case shown in FIG. 6, the wiring from the group of terminals G1 is first bifurcated in the area of the group of terminals G1, followed by further bifurcation in areas that do not overlap the register buffer 300 in a plan view, before connected to the wirings L1 to L4. Branch points of such bifurcations, or branching, are the same contact plug. The same branching occurs for the wirings L5 to L8. According to the present example, the wiring density of the module substrate 110 in the area overlapping the register buffer 300 can be reduced by half as compared to the case of FIG. 6.

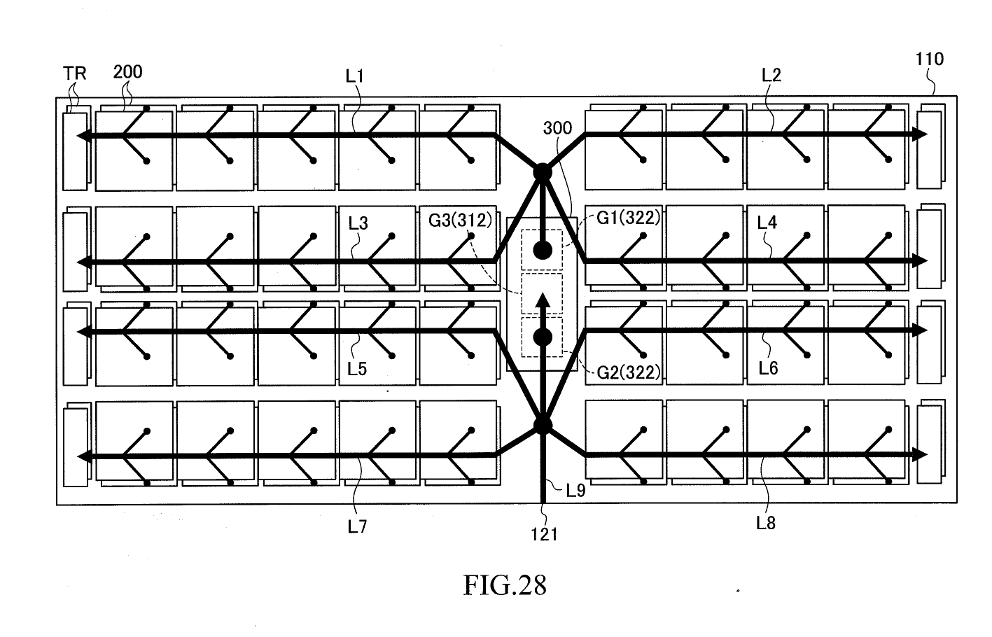

Turning to FIG. 28, like FIG. 6, command address output terminals 322 that are connected to the wirings L1 to L4 are included in the group of terminals G1. Command address output terminals 322 that are connected to the wirings L5 to L8 are included in the group of terminals G2. Unlike the case shown in FIG. 6, the wiring from the group of terminals G1 is first extended from the area of the group of terminals G1 to an area that does not overlap the register buffer 300 in a plan view without branching. The wiring is then branched into the respective wirings L1 to L4 in the area not overlapping the register buffer 300. Branch points of the branching are the same contact plug. The same applies to the wirings L5 to L8. According to the present example, it is possible to reduce the wiring density of the module substrate 110 in the area overlapping the register buffer 300 to one fourth as compared to the case of FIG. 6 without increasing branch points.

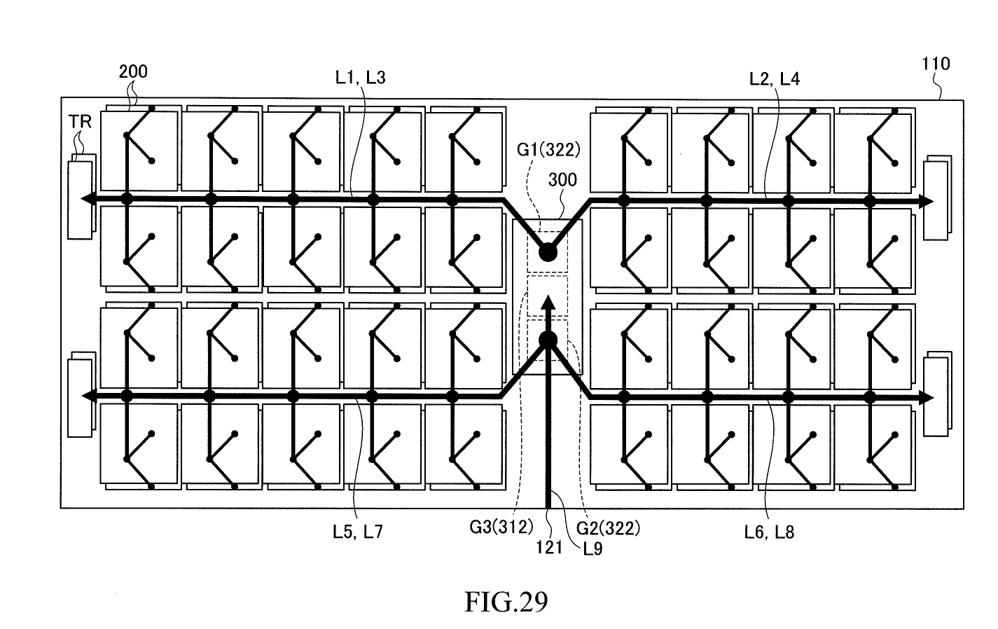

Turning to FIG. 29, the wirings L1 and L3, the wirings L2 and L4, the wirings L5 and L7, and the wirings L6 and L8 are integrated with each other. The wirings are first bifurcated in the areas of the groups of terminals G1 and G2, and then branched for the groups shown in FIG. 9 near the respective groups. According to the present example, the commonality of wiring reduces load. This makes it possible to suppress the power of output buffers for driving command address output terminals 322. The number of termination resistors TR can also be reduced by half.

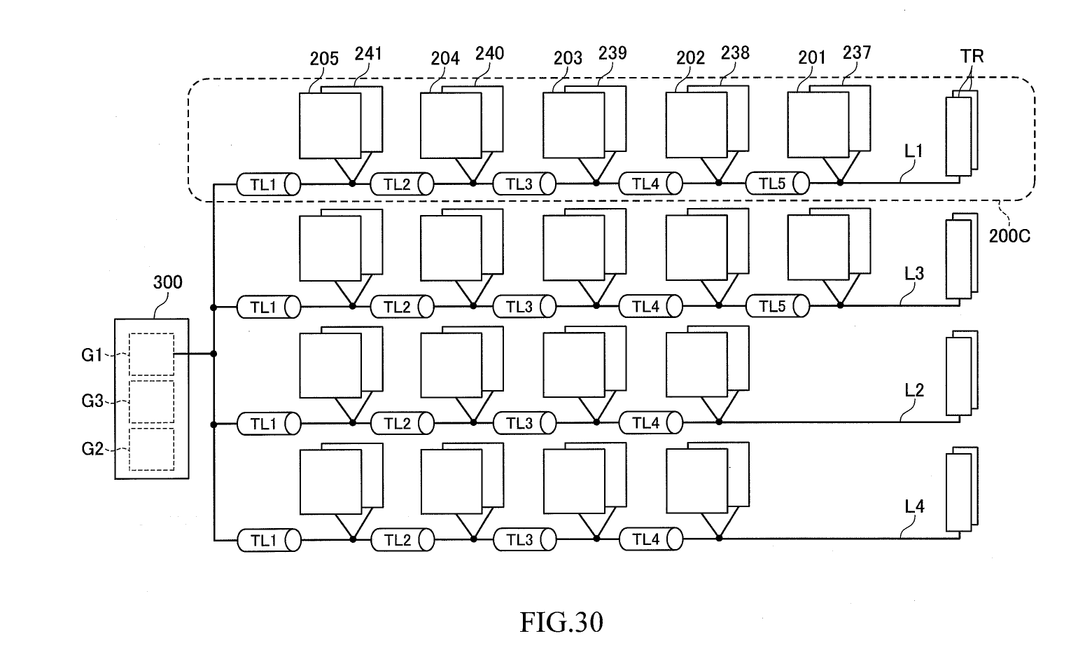

Turning to FIG. 30, there are a plurality of signal lines that have substantial effects on signal characteristics between the register buffer 300 and the memory chips 200. In FIG. 30, TL1 represents signal lines that lie between the register buffer 300 and first memory chips 200. First memory chips 200 refer to memory chips 200 that belong to groups closest to the register buffer 300. TL2 represents signal lines that lie between the first memory chips 200 and second memory chips 200. Second memory chips 200 refer to memory chips 200 that belong to groups second closest from the register buffer 300. The same applies to TL3 to TL5.

Wiring portions other than the signal lines TL1 to TL5 correspond to the wirings p0, p11, and the like shown in FIG. 14. Such portions have little effect on signal characteristics since their wiring lengths are extremely small. In designing the module substrate 110, it is mainly the lengths of the signal lines TL1 to TL5 that need to be taken into consideration.

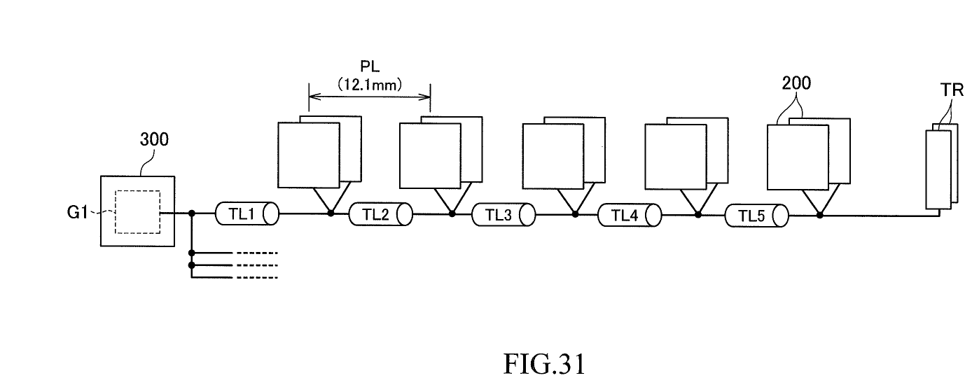

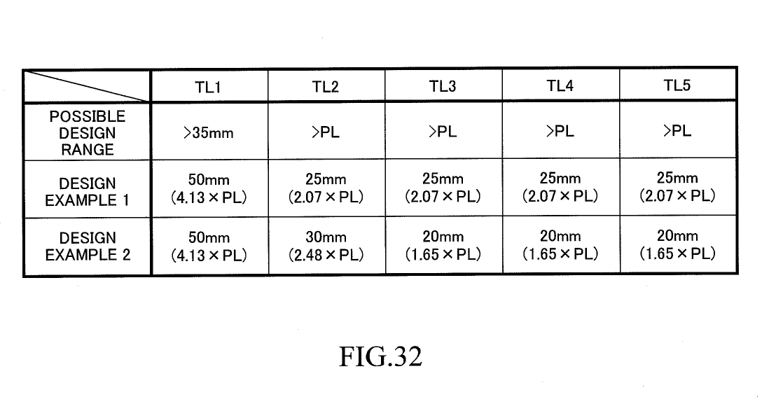

Signal lines TL1 inevitably have a large length not only because of the chip size of the register buffer 300 but also because of the four-row arrangement of the memory chips 200 according to the present embodiment. For example, suppose that a minimum possible design distance of a signal line TL1 is 35 mm. In design examples 1 and 2 shown in FIG. 32, signal lines TL1 are designed to be 50 mm. As shown in FIG. 31, the arrangement pitch of memory chips 200 adjoining in the X direction will be defined as PL. If PL=12.1 mm, then:

TL1=4.13×PL.

In design example 1, all the signal lines TL2 to TL5 are designed to have a length of 25 mm. This makes the line lengths of the signal lines between the memory chips uniform. In terms of the arrangement pitch PL, the lengths of the signal lines TL2 to TL5 according to design example 1 can be expressed as:

TL2 to TL5=2.07×PL.

In design example 2, a signal line TL2 is designed to be longer than signal lines TL3 to TL5. Specifically, the signal line TL2 is designed to be 30 mm, and the signal lines TL3 to TL5 are designed to be 20 mm. In terms of the arrangement pitch PL, the lengths of the signal lines TL2 to TL5 according to design example 2 can be expressed as:

TL2=2.48×PL; and

TL3 to TL5=1.65×PL.

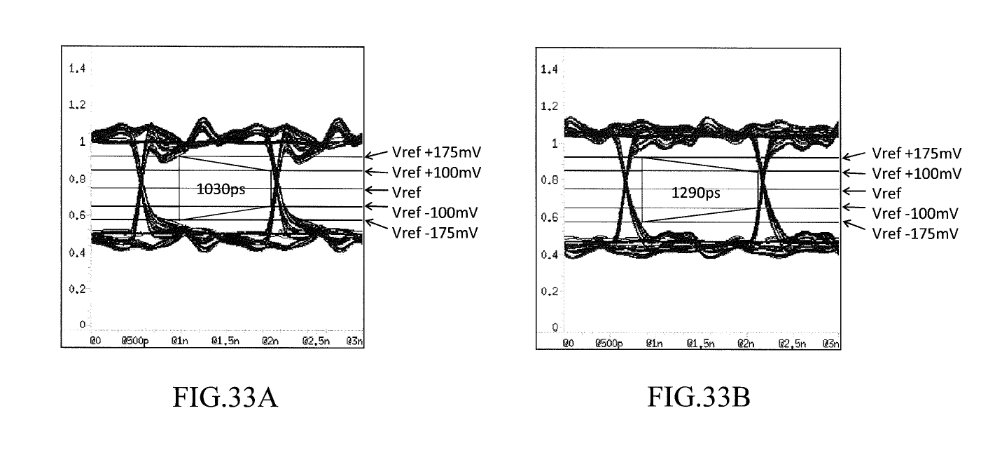

Turning to FIG. 33A, if all the signal lines TL1 to TL5 have the minimum possible design length, command address signals CA have an effective window width of 1030 ps. On the other hand, turning to FIG. 33B, if the signal lines TL1 to TL5 are designed according to design example 1, the effective window width of command address signals CA increases to 1290 ps. Although not shown, if the signal lines TL1 to TL5 have the lengths according to design example 2, a window width equivalent to that of design example 1 is obtained.

It is apparent that the present invention is not limited to the above embodiments, but may be modified and changed without departing from the scope and spirit of the invention.

What is claimed is:

1. A memory module comprising:
a module substrate that includes a plurality of wiring layers including at least first and second wiring layers, and a plurality of contact plugs penetrating through the plurality of wiring layers;
a register buffer that is mounted on the module substrate and includes a plurality of output terminals classified into at least first and second groups; and
a memory chip that is mounted on the module substrate and includes a plurality of input terminals classified into at least first and second groups, wherein
each of the output terminals belonging to the first group is connected to an associated one of the input terminals belonging to the first group through associated ones of the plurality of contact plugs and the first wiring layer, and
each of the output terminals belonging to the second group is connected to an associated one of the input terminals belonging to the second group through associated ones of the plurality of contact plugs and the second wiring layer.

2. The memory module as claimed in claim 1, wherein
the plurality of contact plugs are classified into at least first to fourth groups,
each of the output terminals belonging to the first group is connected to the associated one of the input terminals belonging to the first group through an associated one of the contact plugs belonging to the first group, the first wiring layer, and an associated one of the contact plugs belonging to the third group, and
each of the output terminals belonging to the second group is connected to the associated one of the input terminals belonging to the second group through an associated one of the contact plugs belonging to the second group, the second wiring layer, and an associated one of the contact plugs belonging to the fourth group.

3. The memory module as claimed in claim 2, wherein
the plurality of contact plugs belonging to the third group are arranged in a second direction,
the plurality of contact plugs belonging to the fourth group are arranged in the second direction so as to adjoin the plurality of contact plugs belonging to the third group in a first direction substantially perpendicular to the second direction, and
each of the plurality of contact plugs belonging to the third group and each of the plurality contact plugs belonging to the fourth group do not have the same coordinate in the second direction.

4. The memory module as claimed in claim 1, further comprising an additional memory chip that is mounted on the module substrate and includes a plurality of input terminals classified into at least first and second groups, wherein
the plurality of wiring layers further include third and fourth wiring layers,
each of the output terminals belonging to the first group is connected to an associated one of the input terminals belonging to the first group of the additional memory chip through associated ones of the contact plugs and the third wiring layer, and
each of the output terminals belonging to the second group is connected to an associated one of the input terminals belonging to the second group of the additional memory chip through associated ones of the contact plugs and the fourth wiring layer.

5. The memory module as claimed in claim 2, further comprising an additional memory chip that is mounted on the module substrate and includes a plurality of input terminals classified into at least first and second groups, wherein
each of the output terminals belonging to the first group is connected to an associated one of the input terminals belonging to the first group of the additional memory chip through the associated one of the contact plugs belonging to the first group, the first wiring layer and the associated one of the contact plugs belonging to the third group, and
each of the output terminals belonging to the second group is connected to an associated one of the input terminals of the second group of the additional memory chip through the associated one of the contact plugs belonging to the second group, the second wiring layer and the associated one of the contact plugs belonging to the fourth group.

6. The memory module as claimed in claim 5, wherein
the module substrate further includes first and second surfaces opposing to each other,
the resister buffer and the memory chip being provided on the first surface of the module substrate, and
the additional memory chip being provided on the second surface of the module substrate.

7. The memory module as claimed in claim 5, wherein the resister buffer, the memory chip and the additional memory chip are provided on one surface of the module substrate.

8. The memory module as claimed in claim 1, wherein
the module substrate further includes a plurality of connecter receiving a plurality of address command signals from an outside of the memory module, respectively, and
the resister buffer receiving the address command signals through the connecters and outputting a plurality of internal address command signals based on the address command signals from the output terminals to input terminals of the memory chip, respectively.

9. A module comprising:
a module substrate includes a plurality of wiring layers including at least first and second wiring layers, and first and second contact plugs, each of the first and second contact plugs penetrating through the wiring layers;
a resister buffer mounted on the module substrate and including first and second output terminals; and
a plurality of chips mounted on the module substrate, each of the chips including first and second input terminals, wherein
the first output terminal of the resister buffer is commonly connected to the first input terminals of the chips through the first contact plug and the first wiring layer, and
the second output terminal of the resister buffer is commonly connected to the second input terminals of the chips through the second contact plug and the second wiring layer.

10. The module as claimed in claim 9, further comprising a plurality of additional chips mounted on the module substrate, each of the additional chips including third and fourth input terminals, wherein
the wiring layers of the module substrate further include third and fourth wiring layers,
the first output terminal of the resister buffer is commonly connected to the third input terminals of the additional chips through the first contact plug and the third wiring layer, and
the second output terminal of the resister buffer is commonly connected to the fourth input terminals of the additional chips through the second contact plug and the fourth wiring layer.

11. The module as claimed in claim 10, wherein
the module substrate includes a first area on a surface of the module substrate extending in a first direction and a second area on the surface of the module substrate extending in the first direction in parallel with the first area,
the chips are arranged in the first direction in the first area, and
the additional chips are arranged in the first direction in the second area.

12. The module as claimed in claim 9, further comprising a plurality of additional chips mounted on the module substrate, each of the additional chips including third and fourth input terminals, wherein
the first output terminal of the resister buffer is commonly connected to the third input terminals of the additional chips through the first contact plug and the first wiring layer, and
the second output terminal of the resister buffer is commonly connected to the fourth input terminals of the additional chips through the second contact plug and the second wiring layer.

13. The module as claimed in claim 12, wherein
the module substrate includes a first area on a first surface of the module substrate extending in a first direction and a second area on a second surface opposing to the first surface of the module substrate extending in the first direction and located on a back side of the first area,
the chips are arranged in the first direction in the first area, and
the additional chips are arranged in the first direction in the second area.

14. The module as claimed in claim 12, wherein
the module substrate includes a first area on a surface of the module substrate extending in a first direction, a second area on the surface of the module substrate extending in the first direction and a third area on the surface of the module substrate between the first and second areas,
the chips are arranged in the first direction in the first area,
the additional chips are arranged in the first direction in the second area, and
the resister buffer is provided in the third area.

15. The module as claimed in claim 9, wherein
the first and second output terminals of the resister buffer are arranged in a first direction, and
the first and second input terminals of each of the chips are arranged in a second direction crossing the first direction.

16. The module as claimed in claim 15, wherein
the first and second output terminals of the resister buffer are adjacent to each other, and
the first and second input terminals of each of the chips are adjacent to each other.

17. The module as claimed in claim 9, wherein
the module substrate includes a plurality of connecters receiving a plurality of command address signals from an outside of the module, respectively, and
the resister buffer receives the command address signals through the connecters and outputs first and second internal command address signals based on the command address signals from the first and second output terminals to the first and second input terminals of each of the chips, respectively.
